(19) United States
(12) Patent Application Publication
(10) Pub. No.: US 2025/0110071 A1
(43) Pub. Date: Apr. 3, 2025

(54) USING HYPERPOLARISED 15N DERIVED SYNTHONS TO CREATE HYPERPHARMACEUTICALS THROUGH SABRE

(71) Applicant: UNIVERSITY OF YORK, York (GB)

(72) Inventors: Simon Benedict Duckett, North Yorkshire (GB); Peter Rayner, North Yorkshire (GB); Callum Gater, North Yorkshire (GB)

(73) Assignee: UNIVERSITY OF YORK, York (GB)

(21) Appl. No.: 18/832,632

(22) PCT Filed: Jan. 24, 2023
(86) PCT No.: PCT/GB2023/050149

§ 371 Date: Jul. 24, 2024

(30) Foreign Application Priority Data
Jan. 25, 2022 (GB) 2200964.1

(51) Int. Cl. G01N 24/08

(52) U.S. Cl. CPC G01N 24/088

(57) ABSTRACT

There is described a method for the magnetic resonance studies of a sample using an MRI active ¹⁵N form in solution or liquid comprising: hyperpolarising a 15N-form using SABRE; delivering the hyperpolarised ¹⁵N to a predetermined region of a sample; applying a magnetic field to the sample; exciting the predetermined region of the sample with an excitation pulse suitable for exciting an NMR signal from ¹⁵N in the applied magnetic field; and acquiring magnetic resonance data associated with ¹⁵N from the sample.

### FIELD OF THE INVENTION

The present invention relates to a method for the production of a ¹⁵N-hyperpolarised agent and its subsequent assessment via NMR or MRI.

More particularly, the present invention provides a method for magnetic resonance studies of a sample containing MRI and NMR active ¹⁵N in a variety of species where PHIP is used to provide the initial hyperpolarisation. The initial hyperpolarisation transfer described herein is generally based on the SABRE effect.

The present invention also provides an agent for magnetic resonance studies; the use of hyperpolarised ¹⁵N species; a method of hyperpolarising a substance; a method to detect the chemical transformation of that substance through NMR or MRI apparatus.

### BACKGROUND OF THE INVENTION

Positron emission tomography (PET) is a very sensitive technique that uses gamma cameras to image changes in metabolic processes, blood flow and agent absorption in the body. It takes long-lived radionuclides, output from a cyclotron, and embeds them into suitable receptors to create the radiopharmaceuticals that convey the diagnostic response. Unfortunately, this process can be complex and costly.

Magnetic resonance imaging (MRI) is another powerful diagnostic method, but inherent low sensitivity means routine clinical measurements probe highly abundant water.

Consequently, there has been a great deal of excitement in the clinical community associated with a method called hyperpolarisation that gives MRI the sensitivity needed to visualise changes in metabolic flux by detecting biomolecules that encode disease. The most clinically developed method in this area currently involves the use of dynamic nuclear polarisation (d-DNP).¹⁻² One alternative method to create hyperpolarisation is parahydrogen (p-H₂) induced polarisation (PHIP), which despite being discovered in the 1980's, is only now receiving worldwide attention. Two recent significant PHIP advances that utilise p-H₂ are Signal Amplification by Reversible Exchange (SABRE)³ and p-H₂ induced polarisation with side-arm hydrolysis (PHIP-SAH).⁴ As p-H₂ can be prepared to a level of 50% purity by simply cooling H₂ gas by liquid nitrogen,⁵ one could imagine the wide spread future use of this sensitisation approach.

The expectation is that hyperpolarised pyruvate could transform the clinical diagnosis of diseases such as cancer by tracking pyruvate metabolism and consequently the potential health benefits of this approach are significant.

Pyruvate is in fact the end-product of glycolysis, it is derived from additional sources in the cellular cytoplasm, and is ultimately destined for transport into mitochondria as a fuel input in the citric acid cycle. In mitochondria, pyruvate drives ATP production by oxidative phosphorylation and multiple biosynthetic pathways intersecting the citric acid cycle. Mitochondrial pyruvate metabolism is regulated by many enzymes, including pyruvate dehydrogenase, and pyruvate carboxylase.

Mutations in any of the genes encoding for proteins regulating pyruvate metabolism may lead to disease. Aberrant pyruvate metabolism plays an especially prominent role in cancer, heart failure, and neurodegeneration. Because most major diseases involve aberrant metabolism, understanding and exploiting pyruvate carbon flux may yield novel treatments that enhance human health.

Therefore, pyruvate is a key molecule critical for numerous aspects of eukaryotic and human metabolism. Its ¹³C-hyperpolarisation has been harnessed successfully in the creation of an MRI method to assess abnormalities in pyruvate metabolism that link to cancer.

Unfortunately, it is difficult to see how DNP can be easily scaled up to a widely available technique due to the initial equipment cost, the amount of liquid helium it uses and the small number of samples that such devices can be output daily.

While routine NMR and MRI techniques mainly detect ¹H responses, the next most probed heteronucleus, ¹³C, is 6400 times harder to detect than ¹H. This is due to ¹³C's 1% abundance and small gyromagnetic ratio (γ) which means the Zeeman splitting yielding the resonance frequency is four times smaller than ¹H. Consequently, the macroscopic nuclear magnetisation detected that results from the normally very small nuclear spin-orientation population imbalance is minute. Hyperpolarisation enlarges this imbalance to create bigger signals and it is for this reason that the DNP hyperpolarisation of pyruvate is needed when it is used as a marker to probe for cancer by MRI.

The most common isotope of nitrogen is ¹⁴N, which has a nuclear spin quantum number of 1 and this makes it unsuitable for most NMR and MRI studies. Less utilised ¹⁵N has a highly informative 1350 ppm chemical shift range and long T₁,⁶ but its 0.36% abundant and γ which is 10 times smaller than ¹H combine to make it 277,000 times harder to detect than ¹H; it can, however, be sourced cheaply in reactive materials like ¹⁵NH₄Cl.

Due to the poor signal levels, high concentration samples in conjunction with extensive signal averaging is needed for studies at natural abundance. ¹⁵N NMR though is vital to the examination of proteins and its inefficient detection has driven many of the developments in NMR over the last three decades. We also note that establishing the structures of poly-nitrogen containing compounds that feature widely in drugs is often very hard to achieve due to their sparsity of hydrogen and carbon atoms. Furthermore, the in vivo imaging of such agents is expected to be diagnostic.

U.S. Pat. No. 9,658,300 describes creating hyperpolarised samples of target molecular species through spin transfer from hyperpolarised xenon atoms or other source isotopes. Reversible nanoscale solid state contact is achieved between the hyperpolarised xenon atoms and molecules of a target species. The hyperpolarised target species can then be introduced into a subject of a nuclear magnetic resonance (NMR) experiment.

US Patent application No. 2011/0050228 describes an agent for magnetic resonance studies comprising hyperpolarised ¹⁵N labelled N₂O in solution or liquid ¹⁵N—N₂O.

We have now found that it is possible to turn PHIP into a versatile tool for the preparation of a family of long-lived and highly Magnetic Resonance (MR) visible precursors containing ¹⁵N, akin to the radionuclides of PET. These reactive synthons are then rapidly embedded into important molecular reporters to illustrate the creation of the hyperpharmaceutical. This can be achieved by harnessing species like reactive nitrite (NO₂⁻), nitrate (NO₃⁻), ammonia (NH₃), amines, hydroxylamine (NH₂OH), hydrazine (N₂H₄), azide (N₃⁻), isocyanate (NCO⁻/RNCO) cyanate (OCN⁻/ROCN), thiocyanate (SCN⁻) and nitrosonium (NO⁺) which alongside nitrate, dinitrogen and nitrous oxide (N₂O) can be transformed into useful biological probes. These species reflect some of the key chemicals involved in the life sustaining nitrogen cycle. In fact, many useful hyperpolarised materials could be prepared from this small pool of starting materials and these are reflective of many pharmaceuticals.

### SUMMARY OF THE INVENTION

This success in hyperpolarisation outcome represents an important breakthrough in enabling SABRE for biochemical analysis as it not only dramatically widens the range of agents it works with but improves diagnostic potential more generally.²⁹⁻³² The success in sensitising the ¹H, ¹⁵N, ¹⁹F and ¹³C NMR profiles of these and other materials more generally marks therefore a significant breakthrough in hyperpolarisation which has implications for both NMR and particularly MRI.

Thus, according to a first aspect of the invention there is provided a method for the magnetic resonance studies of a sample using an MRI active agent's ¹⁵N form in solution or liquid comprising:
hyperpolarising a ¹⁵N-form using SABRE;
delivering the hyperpolarised ¹⁵N form to a predetermined region of a sample;
applying a magnetic field to the sample;
exciting the predetermined region of the sample with an excitation pulse suitable for exciting an NMR signal from ¹⁵N in the applied magnetic field; and
acquiring magnetic resonance data associated with ¹⁵N from the sample.

Generally in the method of the present invention various PHIP approaches are used to simply hyperpolarise the MRI or NMR active ¹⁵N forms. This means an imbalance is created in one of the two possible nuclear spin orientations (+½ or −½) of ¹⁵N that is maintained for 10's of minutes if placed in an appropriate magnetic field.⁶

Furthermore, the nitrite ion, usually as sodium nitrite, finds widespread use in the chemical industries, due to its oxidizing properties and role in organic transformations.²⁷

Hyperpolarised ¹⁵N NMR can aid in this process as a further outcome. In this regard, nitrite, such as sodium nitrite, can be used to diazotize many precursors and reflects an important step in many named reactions such Sandmeyer, Pschorr, Gomberg-Bachmann, Balz-Schiemann, Meerwein arylation, Kikukawa-Matsuda, Suzuki-coupling, Heck reaction, Stille cross-coupling. The products of these reactions then find applications as fine chemicals, dyes and pigments, or pharmaceuticals (e.g. prosulfuron, thiazolidinedione derivatives (pioglitazone), O-anisamide and Calpain I inhibitors). Hence, using such protocols provides a transformative approach to improve drug analysis and synthesis.

The azide anion is an excellent nucleophile that readily forms organic azides such as the anti-retroviral AZT. This functionality can be readily reduced to create amines, and through the Curtius rearrangement carbamates. Copper catalysed azide-alkyne cycloadditions or click reactions are also important. Consequently, azide represents an important precursor to agrochemicals, pharmaceuticals and natural products such as Avapro, Diova and Tamiflu.

Normally labelled materials can be examined, and as an example, nitrite ions can be probed by ¹⁵N NMR in solution and the solid state⁷ and used to study chemodenitrification in humic substances⁸ and nitric oxide release from copper (II) sites as examples.⁹

By measuring at 9.4 T, 100% nuclear spin polarisation will improve the ¹⁵N signal strength by 310,000 times its usual level. The sensitivity of PHIP has been used widely in the study of organic and inorganic chemistry and it has made the detection of previously hidden intermediates possible.¹⁰⁻¹³ To date, there is a single report of Na¹⁵NO₂ hyperpolarised by dissolution dynamic nuclear polarisation (d-DNP).

Therefore, the aim of the present invention is to illustrate this hyperpharmaceutical concept by establishing that chemical reactivity can be tracked, and the diagnostic fingerprinting of materials can be performed, thereby dramatically expanding chemical diversity in the field of hyperpolarisation, including the simple creation of very long-lived singlet spin order.

The process may begin with nitrite (NO₂⁻), a reagent that is formed during the nitrification of ammonia by nitrosomas.¹⁹ Whilst mammals do not absorb nitrites directly, plants use it to form essential nitrogen containing molecules such as amino acids and the further aerobic oxidation of nitrite leads to nitrate. Nitrite is used a food additive for cured meats²⁰ and approximately 7% of our ingested nitrite comes this source while the remainder come from nitrate in saliva and stomach through the enterosalivary pathway.²¹⁻²² Furthermore, although nitrites are non-carcinogenic, their ability to form nitrosamines can lead to toxicity²³ as examined by the research community and mainstream media.²⁴⁻²⁵ The action of metmyoglobin production by nitrite is, however, beneficial in the treatment of cyanide poisoning and sodium nitrite remains as one of primary antidotes for acute intoxication.²⁶

In a particular aspect of the invention the source of ¹⁵N may comprise one or more of nitrite (NO₂⁻), ammonia (NH₃), ammonium (NH₄⁺), hydroxylamine (NH₂OH), hydrazine (N₂H₄), nitrosonium (NO⁺), dinitrogen (N₂), nitrate (NO₃⁻), azide (N₃⁻), isocyanate (NCO⁻/RNCO), cyanate (OCN⁻/ROCN), thiocyanate (SCN⁻), amine (RNH₂ etc.) and nitrous oxide (N₂O).

If the source of ¹⁵N contains protons its ²H-counterparts are also included (including combinations of protons and ²H-counterparts) such as ammonia (ND₃, ND₂H and NDH₂), ammonium (ND4⁺, ND₃H⁺, ND₂H₂⁺ and ND₃H⁺), hydroxylamine (NH₂OD, NHDOD, NHDOH, ND₂OD and ND₂OH), amine (RNHD, RND₂, R′RND where R/R′ is a suitable group like alkyl or aryl), hydrazine (N₂D₄, N₂D₃H, N₂D₂H₂ and N₂DH₃) etc.

The presence of nitrosamines as impurities has led to recent drug recalls (valsartan and ranitidine). Hence understanding more clearly pathways to their formation may affect drug manufacture. The method of the present invention provides a route to the detection and quantification of such impurities during synthesis or in the formulation through SABRE.

Nitrite is an ambidentate ligand that can bind via the N— or O— atoms to form nitro or nitrito complexes respectively²⁸⁻²⁹ with Ni³⁰⁻³³ and Pt³⁴⁻³⁶ examples being the most prevalent.

As SABRE works through reversible binding of the agent to become hyperpolarised to a metal complex, we hypothesised that polarisation of NO₂⁻ via this route might be possible.³⁷⁻⁴⁰ There are a few examples of ionic species such as sodium pyruvate,⁴¹⁻⁴² sodium acetate⁴³ and naicin⁴⁴ that undergo SABRE. A scalar coupling network is required to exist between the target analyte and p-H₂ derived protons in the catalyst.⁴⁵⁻⁴⁸ Hence a η¹-NO₂ (N-nitro) form, where any hydride-¹⁵N coupling will be preferred over the η¹-ONO (O-nitrito) and η²-O—N—O (O,O-bidentate) linkage isomers. Theoretical descriptions of SABRE are provided by Barskiy and others^{49, 50, 51} that account for the magnetisation transfer conditions needed.⁵² They are achieved at low magnetic field, typically 6 mT for ¹H, or through r.f excitation at high field⁵³ and drive the sensitisation of ¹H, ¹³C, ¹⁵N, ¹⁹F, ³¹P and ²⁹Si (etc.)^{41-43, 54-64} nuclei provided the catalyst lifetime matches spin-state evolution times.

Typically, when an iridium N-heterocyclic carbene (NHC) catalyst is used, NMR signal strengths that are many orders of magnitude higher than that which would be obtained at thermal equilibrium can be achieved.^{65-66, 67} Warren in particular stands-out for his early work on ¹⁵N⁶⁸ called ¹⁵N-SABRE here, but 79% polarisation has been reported more recently⁶⁹. Tessari has developed analytical science applications⁷⁰ and other catalyst types have been reported.⁷¹ Hyperpolarised long-lived singlet states⁷², as pioneered by Levitt⁷³, have also been created and detected 15 mins. after their formation by ourselves.⁷² However, field dependent ¹⁵N relaxation times can themselves exceed 10 minutes.⁷⁴⁻⁷⁵ These properties are harnessed here to extend utility of the novel SABRE hyperpolarised products.

Thus, one particular benefit is that the hyperpolarised state, if stored in an optimal magnetic field means it may last of several 1000 seconds, which turns these agents into useful synthetic tools like radio labelled precursors for PET, but without the toxicity issues.

By reference to NO₂⁻ we have established that the reaction shown below takes place with [IrCl(COD)(IMes)] and H₂.

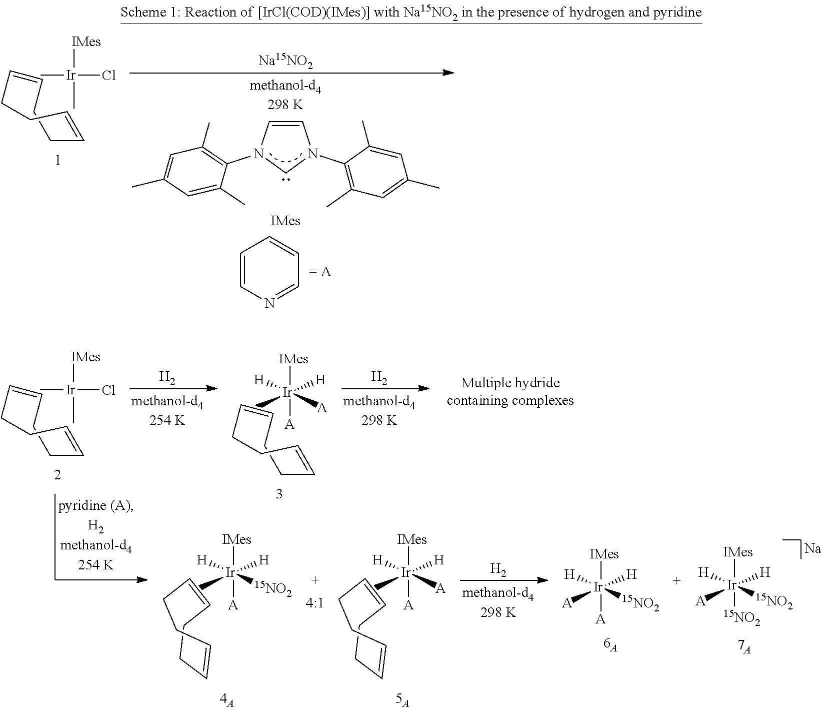

These complexes, depending on the identity of A then enable the SABRE hyperpolarisation of ¹⁵NO₂⁻ in a process whose outcome efficiency is controlled by the magnetic field experienced by the sample during catalysis.

The diagram below demonstrates how this approach leads to a versatile range of feedstocks that allow hyperpharmaceuticals to be created for use in patient diagnostics, synthetic screening, kinetic modelling and/or agent quantification.

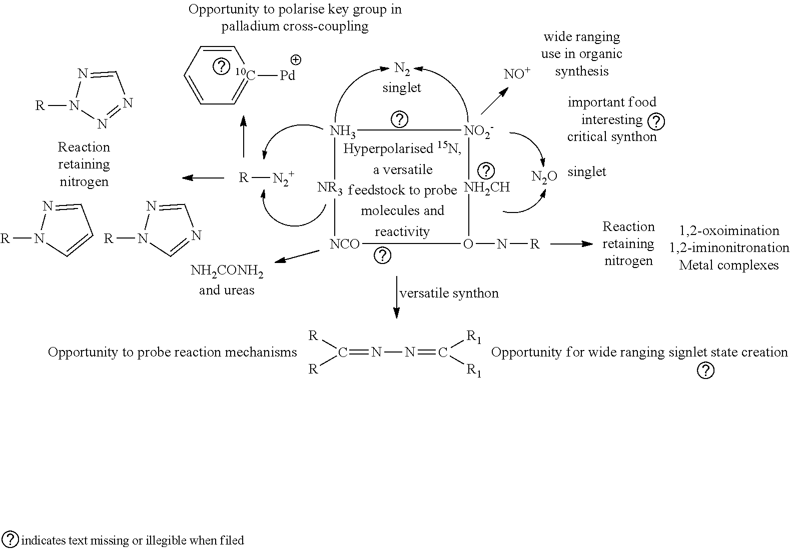

The harnessing of the broad ranging reactivity through nitrogen derived synthons make the realisation of hyperpharmaceuticals possible. For use in living systems, these must be associated with biocompatibility, long-lived magnetisation and high polarisation levels; urea, N₂O, N₂ and glutamate reflecting suitable examples of clinical MRI potential. Similarly, the nitrogen derived synthons may also be useful in the preparation of nitrogen containing PET agents, and the like.

Additionally, the long magnetic state lifetimes and diverse reactivity shown by demonstrate that a diverse portfolio of reaction products can be created that become readily visible to NMR and MRI. For this diverse portfolio of hyperpolarised reaction products we have coined the term “hyperpharmaceuticals”, where synthesis, akin to the production of radiopharmaceuticals, is used to create a versatile range of highly visible agents that may be selected according to their relevance for the future diagnose of disease, since ¹⁵N is a cheap and easily sourced NMR/MRI label.

Thus, according to this aspect of the invention there is also provided a hyperpharmaceutical agent wherein said agent includes a hyperpolarised or hyperpolarisable ¹⁵N moiety.

According to this aspect of the invention there is provided a hyperpharmaceutical agent wherein said agent is created through a reaction involving a ¹⁵N containing hyperpolarised agent and wherein said agent allows the embedding of hyperpolarised nuclei in the hyperpharmaceutical agent reaction product.

There is further provided a method of creating a hyperpharmaceutical agent, said method comprising creating a ¹⁵N containing hyperpolarised agent and wherein the resulting ¹⁵N hyperpolarisation is shared with the hyperpharmaceutical agent through spin coupling driven propagation within the hyperpharmaceutical agent.

In the method of creating a hyperpharmaceutical agent said method comprises maximising its utility by creating a (i) more diagnostic or (ii) longer lived or (iii) stronger response.

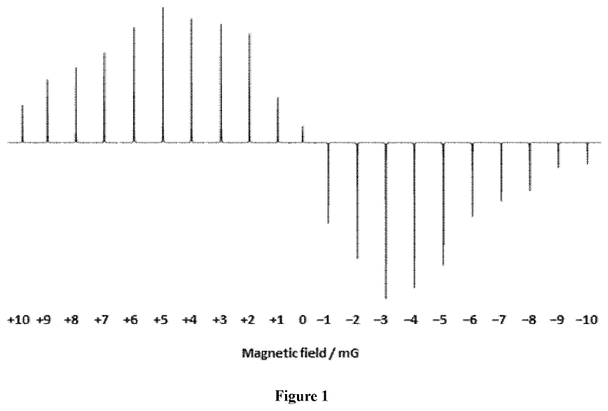

The effect of polarisation transfer field on the SABRE polarisation of Na¹⁵NO₂ in the presence of pyridine is illustrated in FIG. 1 and harnessing such effects represents a way to optimise the delivered hyperpolarisation.

According to a particular aspect of the invention the step of hyperpolarisation includes the use of a SABRE hyperpolarisation catalyst.

The hyperpolarisation may be achieved by polarisation transfer after, spin refrigeration, DNP, para-hydrogen induced polarisation (PHIP), SABRE or from a suitable molecule in a singlet state. However, in one particular aspect of the invention the hyperpolarisation is introduced by SABRE and thus, the transfer catalyst is a magnetisation transfer catalyst, especially a SABRE magnetisation transfer catalyst.

There are a number of ways to induce certain nuclei into a hyperpolarised state. The simplest way is to cool the material to very low temperatures in the presence of a magnetic field, which will favour population of the lower energy state in which the spins of the nuclei are aligned with the applied magnetic field. This method is suitable for the production of hyperpolarised monatomic gases such as xenon or helium-3. The polarisation levels of these nuclei have also been increased via the use of laser-based technologies.

In SABRE, a catalyst reversibly binds p-H₂ and the polarisable molecule to transfer dormant spin order from p-H₂ into the substrate via a scalar-coupling framework to the target molecule.

If there are two NMR active spins accepting polarisation, as exemplified by ¹³C₂ pyruvate, this will result in a singlet state in the polarisable molecule which will desirably be characterised by a long lifetime in a low magnetic field if there are two scalar coupled spin ½ nuclei present. Preferably, the resulting singlet state lifetime will be 20 seconds or more, preferably more than 20 seconds or more than 25 seconds or more than 30 seconds. The resulting singlet state lifetime may last one or more minutes. For the case of ¹⁵N, this is exemplified by N₂O, N₂H₄, and R′₂CN—NCR₂ where R and R′ are suitable groups (viz aromatic, aliphatic etc.).

When a SABRE type process is utilised as the method of hyperpolarisation, a SABRE hyperpolarisation catalyst (e.g. [IrCl(COD)IMes] or a ²H-labelled counterpart or a related catalyst may be used to optimise the process in a suitable solvent with the selected singlet state derived agent. A co-ligand may be added to promote SABRE for NO₂⁻, NO₃⁻ (etc.).

The co-ligand will be selected according to its binding properties, which must relate to those of NO₂⁻, NO₃⁻ (etc.). Thus if the selected co-ligand binds too strongly it will suppress NO₂⁻, NO₃⁻ (etc.) binding and be detrimental to SABRE. However, if it binds too weakly, the iridium catalyst will cease to have a suitable lifetime. The co-ligand is exemplified, but not limited to DMAP, DSMO, pyridine, NH₃ and NH₂Ph (or their deuterated forms).

H₂ or parahydrogen (p-H₂) gas may be the selected singlet state derived agent and after being added to the resulting system whilst agitating the system will activate the catalyst through a reaction whose speed may be enhanced by stirring, warming or shaking. Alternatively, the application of ultrasound may be used as a means of agitation. Hyperpolarisation transfer, by replacing the H₂ gas with p-H₂ may be performed to create a hyperpolarised transference complex whilst agitating the system as described herein. The addition of H₂ or parahydrogen (p-H₂) gas to the solvent may take place prior to the solvent system being agitated or may take place concurrent with agitation. Catalyst activation under parahydrogen may take place prior to the final hyperpolarisation transfer step or be part of the hyperpolarisation transfer step.

The co-ligand (L) and the other ligands surrounding the catalyst may include ²H labels in order to make the hyperpolarisation transfer process more selective and or efficient.

Hyperpolarisation will be transferred from parahydrogen into the polarisable target molecule in an optimised magnetic field to create a strongly hyperpolarised response. This may be subsequently converted into a singlet state across the spin-pair if desired. This conversion may occur spontaneously and optimised by selection of an appropriate magnetic field(s) for transfer or may be promoted by radio frequency excitation. It will be understood that a mixture of transfer catalysts may be included in the method of the invention to improve selectivity and allow mixtures to be examined.

The magnetic field can be changed to focus or improve the efficiency of hyperpolarisation transfer. The type of magnetic states required in this process may be ultra-low magnetic fields, e.g. <<1G (<10⁻⁶T) which can spontaneously hyperpolarise the said singlet state. A change in magnetic field can be used to control which substrates in a mixture gain signal in order to introduce selectivity, while varying the field during transfer step to enhance the signal from all substrates. Hence it will be possible to use this magnetic field to optimally polarise the MR active nuclei in the target substrate rather than the ligand L.

It will be understood that a mixture of target molecules may be included in the method of the invention.

It will also be understood that in the conjugate acid forms, the protons on these agents can be removed by the addition of a base such as NaOH or Cs₂CO₃ to form the corresponding anion in order to further optimise lone pair availability. This route can improve binding to the catalyst and thereby increase SABRE efficiency.

The target molecule will then contain at least one —NH and may comprise an amine or amide moiety. Thus, a polarisable molecule containing at least one —NH may comprise, individually or in combination, a primary, secondary or tertiary amine, such as NH₃, NH₂OH, N₂H₄, NH₂Ph, NH₂CH₂Ph, NH₂CH₂HCH₂CH₂Ph and related amines; or an amide, such as NH₂COCH₃ or NH₂CONH₂; and the like. An amine or amide can be used to control the efficiency of hyperpolarisation transfer. For NO₂⁻, it is HNO₂, while for NO₃⁻ it is HNO₃.

Illustrative examples of target molecules which may be hyperpolarised via this route include, but shall not be limited to:
(i) NR′R″R′″ wherein R′, R″ and R′″, which may be the same or different, each represents H, alkyl_{C1-20}, aryl, base pair, etc. and combined in structures like glutamine, glutamate and GABA;
(ii) NR′R″COR′″ wherein R′, R″ and R′″, which may be the same or different, each represents R′, R″ or R′″═H, CH₃, alkyl, aryl, vinyl, or any combination exemplified by acetamide, urea, glutamine, glutamate, and the like;
(iii) carbazides with general formula RR′N—NH(C═O)NH—NR″R′″ wherein R, R′, R″ and R′″ which may be the same or different, each represents R′, R″ or R′″═H, CH₃, alkyl, aryl, vinyl, or any combination.
(iv) nitrogen containing platinum derived cancer drugs, which include, but shall not be limited to cisplatin, carboplatin, nedaplatin, oxaliplatin, triplatin, satraplatin; and the like; and
(v) cancer drugs containing an acetamide group, which include, but shall not be limited to, taxanes such as paclitaxel, docetaxel, cabazitaxel; and the like.

Generally in the method of the invention the step of hyperpolarisation includes the use of a SABRE hyperpolarisation catalyst.

The SABRE hyperpolarisation catalyst will usually comprise a transition metal complex, for example comprising a metal atom selected from, but not limited to, Ru, Rh, Ir, W, Pd and Pt. In a particular aspect of the present invention, a SABRE hyperpolarisation catalyst may comprise an iridium-based catalyst whose key identity is controlled by the co-ligand.

The nature of the catalyst may vary, but may, for example, take the form of a conventionally known hydrogenation catalyst. Thus, such catalysts may be homogeneous catalysts, for example, Wilkinson's catalyst, or heterogeneous catalysts, such as Pd on carbon. Thus, such homogeneous catalysts may include, but shall not be limited to, rhodium based catalysts, such as Wilkinson's catalyst and iridium based catalysts, such as Crabtree's catalyst. Heterogeneous catalysts may comprises one or more platinum group metals, particularly platinum, palladium, rhodium and ruthenium, precious metal catalysts, such as silver or gold, or non-precious metal catalysts, such as those based on nickel, e.g. Raney nickel.

Examples of preferred (SABRE) hyperpolarisation transfer precatalysts are thus described in International patent application No. PCT/GB2009/002860. Such catalysts include, for example, [IrCl(COD)(IMes)] and analogues thereof, (in which COD is cycloocta-1,5-diene). Alternatively, the SABRE hyperpolarisation catalyst may comprise a ²H-labelled counterpart of [IrCl(COD)(IMes)] or a catalyst optimised to work in the non-aqueous phase with the selected substrate. Alternatively, the SABRE hyperpolarisation catalyst may comprise of either of the two previous modifies in conjunction with a form like [IrL(COD)(IMes)]Cl which already contains L or a catalyst optimised to work in the non-aqueous phase with the selected substrate. Generally, an iridium magnetisation transfer catalyst will include iridium with at least one N-heterocyclic carbene (NHC) ligand or phosphine.

Examples of such N-heterocyclic carbenes include, but shall not be limited to:

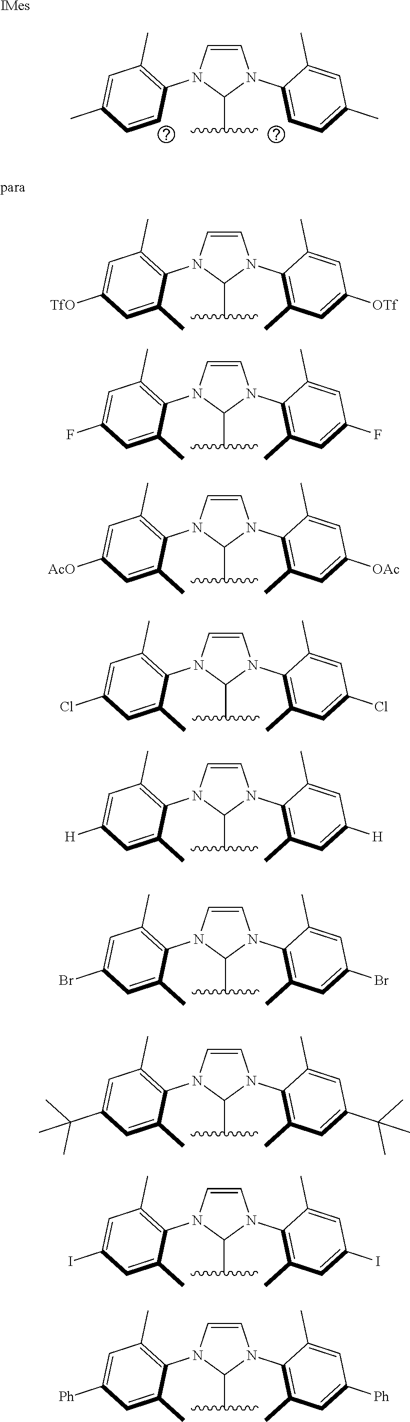

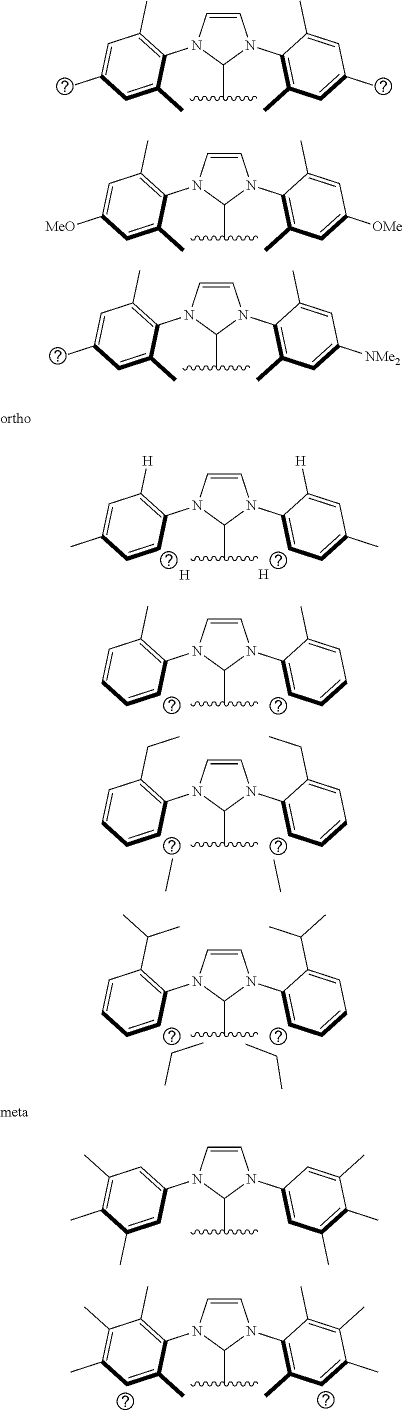

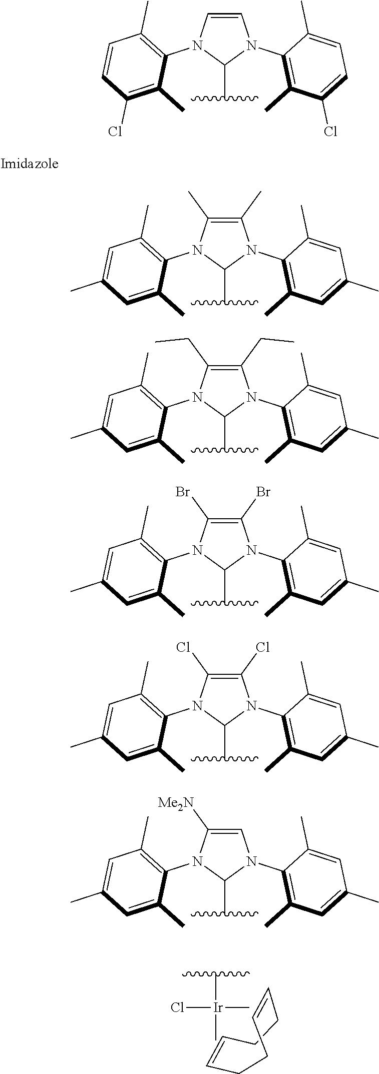

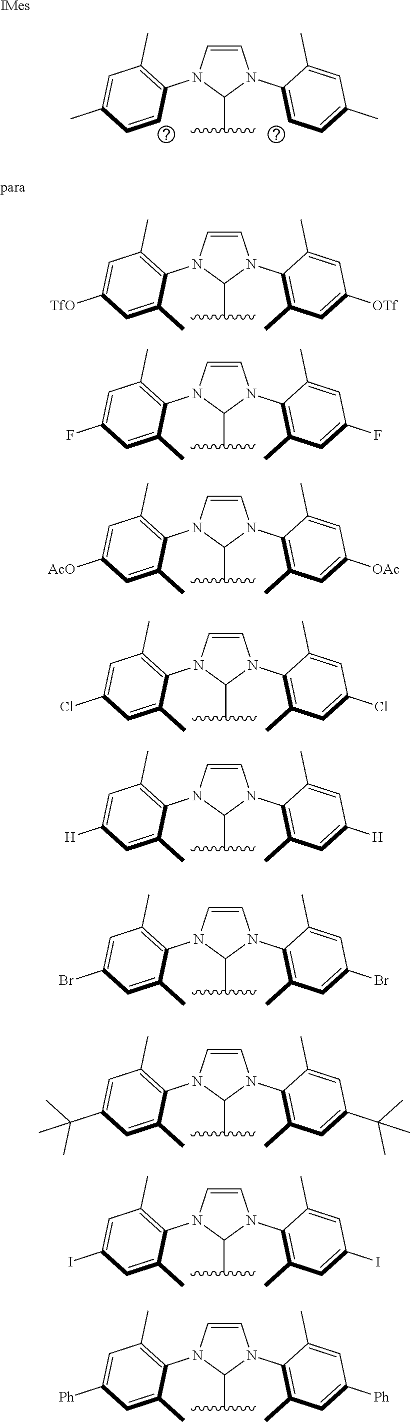

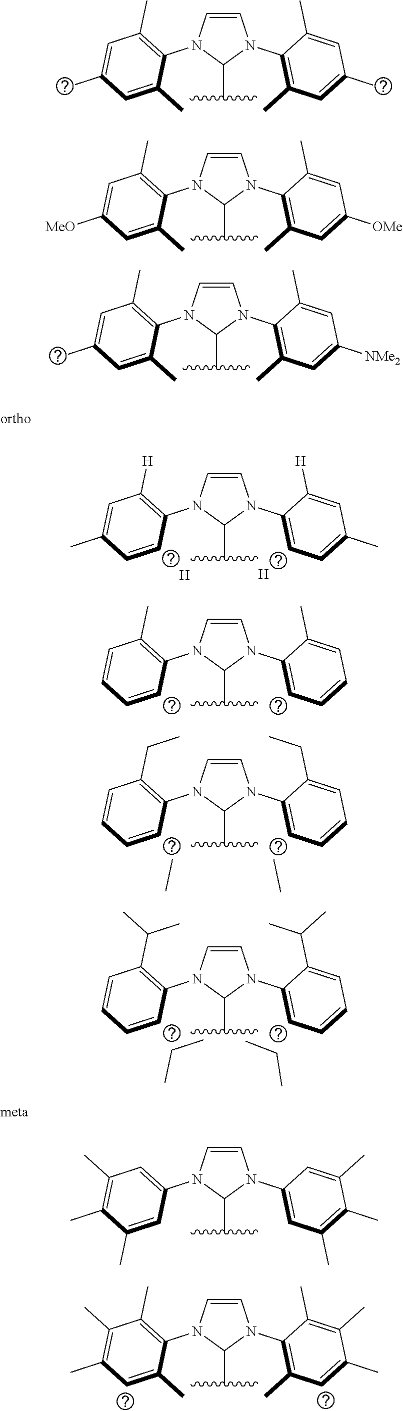

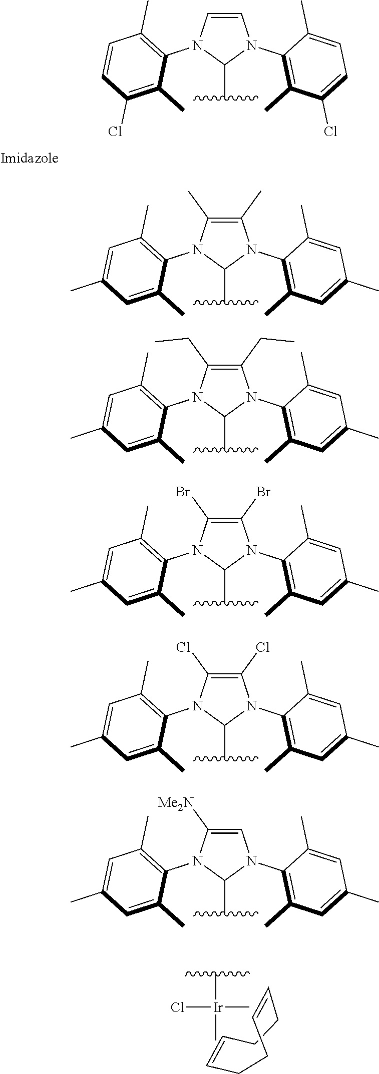

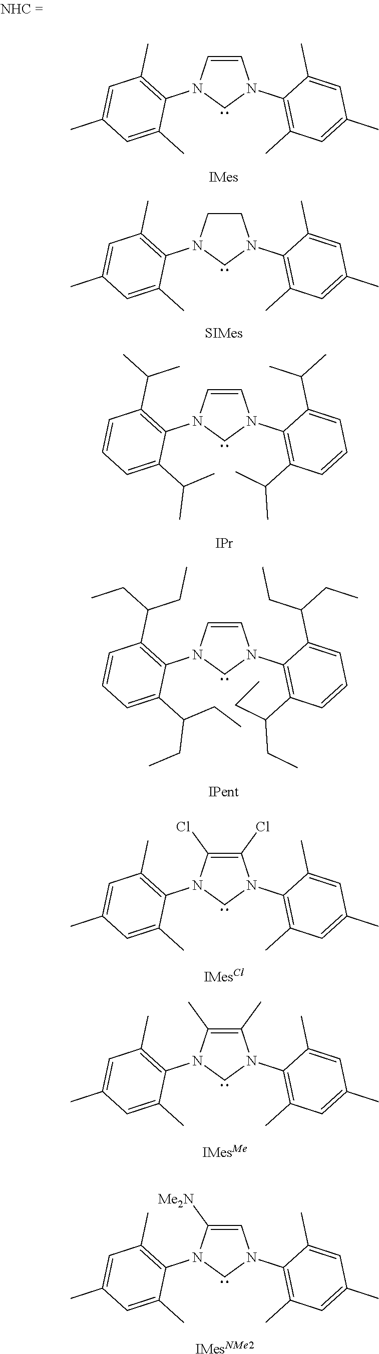

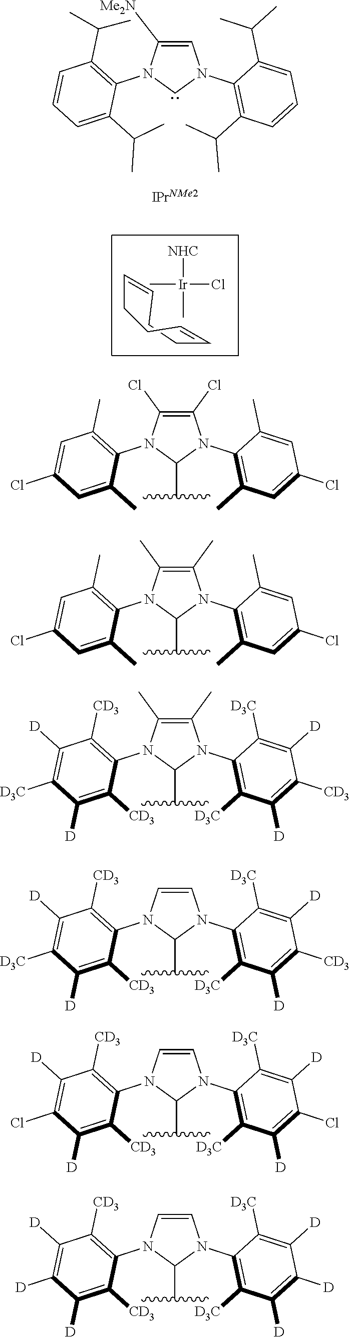

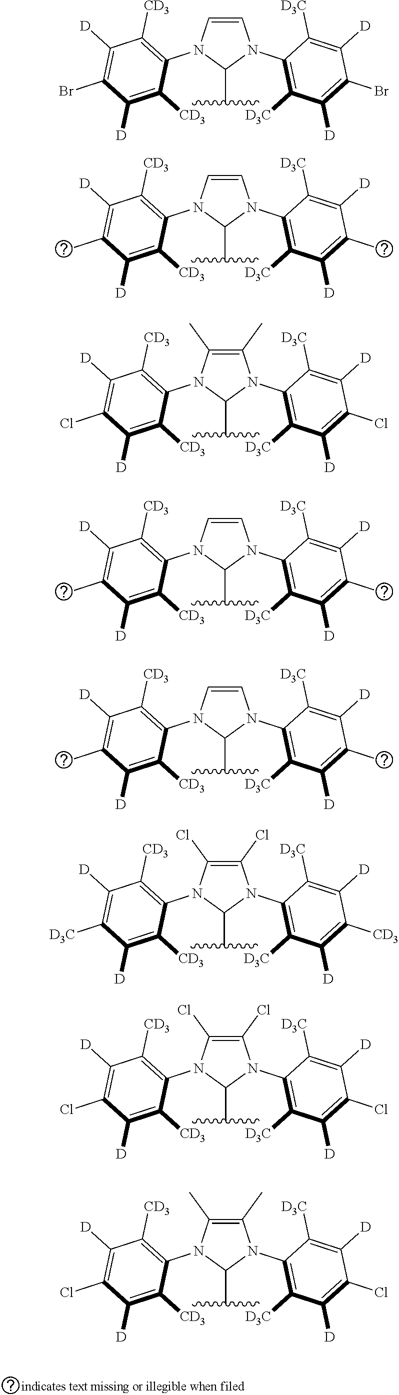

The transfer catalyst may be designed to produce an optimal lifetime and coupling framework for hyperpolarisation transfer under these conditions. It will be understood that a mixture of transfer catalysts may be included in the method of the invention.

These species are often referred to as precatalysts because they are stable and become active during the catalytic process, in this case through their reaction with the small molecule substrate, the co-ligand L and H₂.

The co-ligand may be selected from the group consisting of one or more of a sulfoxide, a thioester, a phosphine, an amine, CO, an isonitrile and a nitrogen heterocycle. A particular example of a co-ligand is one or more sulfoxides, although other co-ligands are contemplated herein. Examples of sulfoxide co-ligands include a wide range of sulfoxides, such as, alkylsulfoxides, including, but not limited to, dimethylsulfoxide, diethylsulfoxide, dibutylsulfoxide and methylethylsulfoxide; and arylsulfoxides, including, but not limited to, diphenylsulfoxide, dibenzysulfoxide, phenylmethylsulfoxide, phenylethylsulfoxide, phenylvinyl sulfoxide and dimesityl sulfoxide (1,3,5-trimethyl-2-(2,4,6-trimethylphenyl)sulfinylbenzene); depending on the identity of the target analyte (illustrated above for pyruvate), the polarisation transfer mechanism, and the desire to create singlet polarisation in a suitable spin pair or Zeeman polarisation, the need for biocompatibility, the identity of the NHC and the choice of solvent.

The co-ligand will generally be bound to a SABRE catalyst.

A variety of solvents may be used in preparing the fluid required for the method of the present invention. Such solvents will generally be organic solvents, e.g. a non-aqueous solvent; and may comprise polar, non-polar solvents, non-protic and protic solvents. Such solvents include, but shall not be limited to H₂O, CH₃OH, CH₃CH₂OH, CH₂OH, CH₂Cl₂, CHCl₃, THE, DMF, nitromethane, alkanes and aromatic hydrocarbons, such as benzene or toluene; the deuterated counterparts of any of the aforementioned solvents. Selection of an appropriate solvent may be used to control one or more of the steps herein defined in the method of the invention.

According to a further aspect of the invention a biphasic element may be introduced into the solvent in order to separate the hyperpolarised target molecule from the transfer catalyst.

When SABRE hyperpolarisation is used, a SABRE hyperpolarisation catalyst (e.g. [Ir(Cl(COD)(IMes)] or a ²H-labelled counterpart or one containing L or a catalyst optimised to work in the polar phase with the selected singlet state derived substrate).

When the agent to be hyperpolarised is an anion, like NO₂⁻ or NO₃⁻ a phase transfer promoter like a crown ether, aza-crown ether, thia-crown ether, cyclodextrin, cryptophane or cryptand may be used in conjunction with a cation like Na⁺ or K⁺ to improve solubility.

When a mixed solvent system is used a solvent phase-separation promoter e.g. NaCl or NaO₂CCH₃ or NaOH or NaHCO₃ or Na₂CO₃ or ethanol, at a suitable concentration may be added to the system.

The concentration of the phase-separation promoter may be an amount suitable to:
(i) achieve physiological conditions;
(ii) vary the solutions pH to achieve optimal SABRE;
(iii) optimise organic phase extraction; and/or
(iv) optimise the speed of phase-separation.

Any known phase-separation promoter may be used. Desirably such a phase-separation promoter will be suitable for in vivo use and therefore should be suitable to achieve physiological conditions. In addition, the phase-separation promoter should be suitable to withstand variations in pH which may be desirable to achieve optimal SABRE. Selection of the phase-separation promoter may also be desirable to optimise organic phase extraction; and/or to optimise the speed of phase-separation. Examples of phase-separation promoters include alkali metal salts, such as sodium or potassium salts; or alkaline earth metal salts, such as calcium. Alkali metal salts are preferred, such as NaCl, or NaO₂CCH₃, NaOH, NaHCO₃ or Na₂(CO₃). A further phase-separation promoter may comprise an alcohol such as ethanol.

The amount of phase-separation promoters may vary depending, inter alia, upon the nature of the phase-separation promoters, the nature of hyperpolarisation target, etc. When the aim is to create a biocompatible system, NaCl or KCl may be used as a phase-separation promoter to produce a saline or saline-like solution. Therefore, the amount of the phase-separation promoter may vary depending upon, inter alia, the nature of the phase-separation promoter. Generally, the phase-separation promoter may be from about 0.33% w/v to about 9% w/v. However, it will be understood by the person skilled in the art that more or less of the phase-separation promoter may be included, as required.

The hyperpolarisation transfer may be performed with p-H₂ to create a hyperpolarised target molecule whilst agitating the biphasic solvent as herein described.

An appropriate amount of time may be allowed to enable the two solution phases to separate.

Through the process described herein the NMR or MR response of the target molecule can be increased so that it is readily detectable in a high resolution or imaging experiment.

The hyperpolarisation target molecule may reflect one or more of nitrite (NO₂⁻), ammonia (NH₃), ammonium (NH₄⁺), hydroxylamine (NH₂OH), hydrazine (N₂H₄), nitrosonium (NO⁺), dinitrogen (N₂), nitrate (NO₃⁻), azide (N₃⁻), isocyanate (NCO⁻/RNCO), cyanate (OCN⁻/ROCN), thiocyanate (SCN⁻) and nitrous oxide (N₂O).

If the source of ¹⁵N contains protons its ²H-counterparts are also included such as ammonia (ND₃, ND₂H and NDH₂), ammonium (ND₄⁺, ND₃H⁺, ND₂H₂⁺ and ND₃H⁺), hydroxylamine (NH₂OD, NHDOD, NHDOH, ND₂OD and ND₂OH), hydrazine (N₂D₄, N₂D₃H, N₂D₂H₂ and N₂DH₃) etc.

It may also be the product of a reaction involving one of the above agents, which are now acting as synthons to a more complex molecule, or the hyperpharmaceutical. These will be prepared in a synthetic step(s) that individually or in combination proceed more rapidly than the ¹⁵N T₁ relaxes the created hyperpolarisation.

The use of L (e.g. DMSO, diethylsulfoxide, (etc.)) can be used to control the efficiency of hyperpolarisation transfer in the first step. This is a result of the metal complexes reactivity, which can be optimised for specific solvent, cost, pressure of p-H₂ and time of activation.

The temperature can be changed to focus or improve the efficiency of hyperpolarisation transfer.

We note, more than one target may be present.

The transfer catalyst will usually comprise a transition metal complex, for example comprising a metal atom selected from, but not limited to, Ru, Rh, Ir, W, Pd and Pt. The transfer catalyst will usually comprise one or more ligands in addition to the ligand comprising the hyperpolarisable nuclei. These one or more other ligands may comprise organic or inorganic ligands and may be mono-, bi- or multidentate in nature. These one or more ligands may play a role in controlling the activity and stability of the metal centre. For example, the one or more ligands may comprise NHC ligands as herein described while the other ligand may be a sulfoxide.

In one embodiment, the transfer catalyst comprises one or more phosphine/co-ligand combinations in addition to the ligand to be hyperpolarised. The transfer catalyst may be attached to a solid support, for example a polymer support. Attachment will usually be made through a ligand which links the metal centre to the support. Suitable linkers are known in the art. For example, the linker may comprise one or more in-chain atoms selected from C, O, N, S, P and Si. The linker may comprise a siloxane moiety for attachment to the support and/or a phosphine moiety for attachment to the metal of the complex. In embodiments, the linker is a group of the following formula: —O—Si(OMe)₂-(CH₂)ₙ—P(Cy)₂-, wherein n is 0 upwards (e.g. 0, 1, 2, 3, 4, 5 or 6) and Cy is cyclohexyl.

In a further embodiment, the NHC or phosphine and co-ligand are linked together and form what is known as a chelate. This can be achieved via appropriate substitutions and the NHC/phosphine and co-ligand. Both cis and trans spanning may be induced by changing the length of the spacer. In this case the pre-catalyst is preassembled to include the co-ligand L.

For in vivo use an in-line UV probe may be used, if desired, to establish that the concentration of the catalyst is sufficiently for in vivo injection. This makes full use of the fact that the catalyst is no longer present and therefore unable to promote the relaxation of the agent, thereby maximising longevity of the resulting hyperpolarised signal.

For systems where the catalyst concentration remains too high, a catalyst deactivator may be added after the polarisation transfer step, or the synthetic step(s). Examples of suitable catalyst deactivators include, but shall not be limited to a chelating ligand, such as, bipyridyl, EDTA and dimethylglyoxime. A catalyst deactivator can be added to facilitate catalyst release.

An appropriate delivery device may be used to procure the hyperpolarised target molecule for detection by NMR or MRI which can facilitate some or all of the following:

Using an appropriate delivery device to procure the hyperpolarised agent for detection by NMR or MRI which will facilitate some (all) of the following:
(i) after an appropriate time removing a hyperpolarised sample from the aqueous phase or solvent;
(ii) using UV monitoring to assess suitability immediately prior to sample removal or after sample removal;
(iii) using pH monitoring to assess suitability immediately prior to sample removal or after sample removal;
(iv) employing filtration to achieve sterility after sample removal;
(v) injecting or transporting the sample into a target for subsequent detection by NMR or MRI, where the target might be a suitable sample tube, an animal or a human.

In summary, we have illustrated a novel approach to hyperpolarise ¹⁵N directly by the SABRE hyperpolarisation technique.

In order to further optimise this process the sulfoxide ligand can be changed with suitable representative examples being diphenyl sulfoxide, dibutyl sulfoxide, dibenzyl sulfoxide, phenylmethyl sulfoxide, phenylethyl sulfoxide, phenylvinyl sulfoxide, dimesityl sulfoxide.

In addition, the NHC can be varied according to the earlier figure in conjunction with the sulfoxide to further optimise this process for a given substrate.

According to a further aspect of the invention there is provided an agent for magnetic resonance studies, the agent comprising SABRE hyperpolarised ¹⁵N in solution or liquid ¹⁵N.

The source of ¹⁵N may comprise one or more of nitrite (NO₂⁻), ammonia (NH₃), hydroxylamine (NH₂OH), hydrazine (N₂H₄), nitrosonium (NO⁺), nitrate and dinitrogen.

In a particular aspect of the invention the source of ¹⁵N may comprise one or more of nitrite (NO₂), ammonia (NH₃), ammonium (NH₄⁺), hydroxylamine (NH₂OH), hydrazine (N₂H₄), nitrosonium (NO⁺), dinitrogen (N₂), nitrate (NO₃⁻), azide (N₃⁻), isocyanate (NCO⁻/RNCO), cyanate (OCN⁻/ROCN), thiocyanate (SCN⁻) and nitrous oxide (N₂O).

If the source of ¹⁵N contains protons its ²H-counterparts are also included such as ammonia (ND₃, ND₂H and NDH₂), ammonium (ND₄⁺, ND₃H⁺, ND₂H₂⁺ and ND₃H⁺), hydroxylamine (NH₂OD, NHDOD, NHDOH, ND₂OD and ND₂OH), hydrazine (N₂D₄, N₂D₃H, N₂D₂H₂ and N₂DH₃) etc.

The solution may comprise at least one selected from water, blood, oxygenated blood, deoxygenated blood, plasma, fat or oil.

In a preferred aspect of the invention the imaging medium comprises a solution of a target molecule in a saline solution of a hyperpolarised target molecule.

According to a further aspect of the invention there is provided the use of SABRE hyperpolarised ¹⁵N in solution or liquid as an agent in the methods as herein described.

In particular there is provided the use of hyperpolarised ¹⁵N wherein the source of ¹⁵N comprises one or more of nitrite (NO₂⁻), ammonia (NH₃), ammonium (NH₄⁺), hydroxylamine (NH₂OH), hydrazine (N₂H₄), nitrosonium (NO⁺), nitrate, dinitrogen, nitrate (NO₃⁻), azide (N₃⁻), isocyanate (NCO⁻/RNCO), cyanate (OCN⁻/ROCN), thiocyanate (SCN⁻) and nitrous oxide (N₂O) of their reaction products.

According to a further aspect of the invention there is provided a method of hyperpolarising a substance, the method comprising:
liquefying the SABRE hyperpolarised ¹⁵N agent;
dissolving the substance to be hyperpolarised in said liquefied ¹⁵N agent; and
removing said ¹⁵N that is now converted to a product.

According to a further aspect of the invention there is provided an MRI apparatus comprising:
means to apply a magnetic field to a SABRE hyperpolarised sample;
means to apply RF radiation to the sample; and
means to detect an NMR signal arising from the sample due to the application of the magnetic field and RF radiation, wherein the means to apply a magnetic field and the means to apply RF radiation are configured to excite an NMR signal from ¹⁵N; and
wherein the means to detect an NMR signal are configured to detect an NMR signal from ¹⁵N.

The invention will now be illustrated by way of example only and with reference to the accompanying drawings, in which:

FIG. 1 illustrates the effect of polarisation transfer field on the SABRE polarisation of Na¹⁵NO₂ in the presence of pyridine;

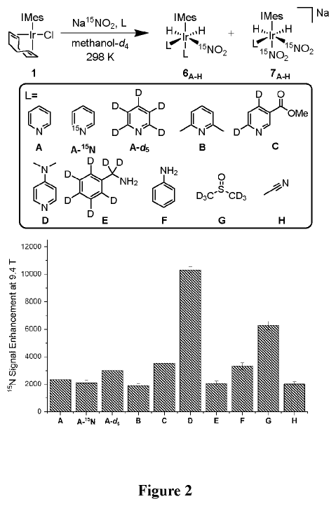

FIG. 2 illustrates the effect of co-ligand, A-H, on the SABRE polarisation level found for Na¹⁵NO₂ after reaction of [IrCl(COD)(IMes)] with Na¹⁵NO₂ (25 eq.) and the co-ligand (4 eq.) in methanol-d₄ at 298 K. The ¹⁵N signal enhancements for Na¹⁵NO₂ result after polarisation transfer under 3 bar p-H₂ in a −3.5 mG field;

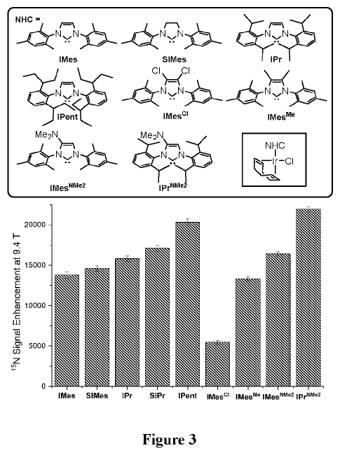

FIG. 3 illustrates the effect of NHC identity on the ¹⁵N NMR signal enhancement level for Na¹⁵NO₂ based on using the precatalyst [IrCl(COD)(NHC)](5 mM), DMAP-d₂ (6 eq.) and Na¹⁵NO₂ (25 eq.) in methanol-d₄ with polarisation transfer at −3.5 mG under 3 bar p-H₂;

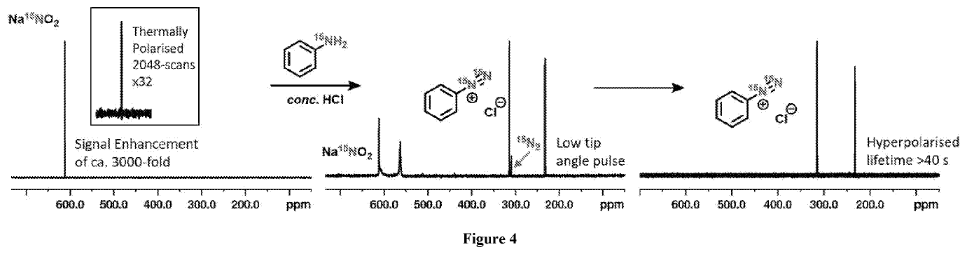

FIG. 4 illustrates the conversion of nitrite into a diazonium cation and N₂ as revealed by hyperpolarised ¹⁵N NMR thereby illustrating the hyperpharmaceutical concept. This starts with hyperpolarised ¹⁵NO₂⁻. A hyperpolarised response for ¹⁵N₂ is noteworthy, alongside the efficient sharing of polarisation into both of the ¹⁵N coupled spins in the product even though only one is initially polarised;

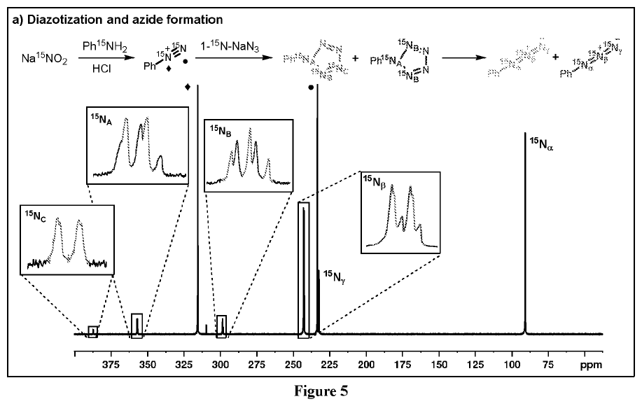

FIG. 5 illustrates utilizing the reactivity of Na¹⁵NO₂ towards aniline-¹⁵N to enable the tracking of diazotization with the product reacting with mono-¹⁵N labelled sodium azide to subsequently form of two isotopomers of phenyl azide via a normally invisible cyclic intermediate;

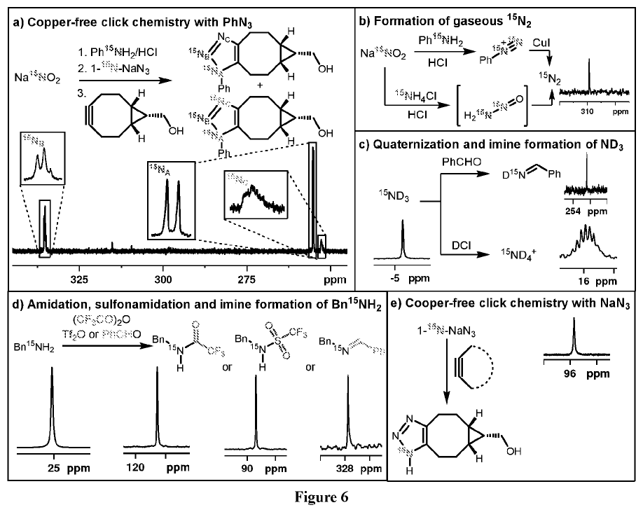

FIG. 6 illustrates the utilization of hyperpolarized ¹⁵N NMR spectroscopy to probe: a) copper free click chemistry of hyperpolarised PhN₃, formed as in FIG. 5; b) two routes to the formation of hyperpolarized N_{2 (g)}; c) Quaternization of an amine with DCl(aq) and the corresponding imine formation with benzaldehyde; d) Amidation, sulfonamidation, imine formation utilizing benzylamine-¹⁵N; e) the copper free-click chemistry with 1-¹⁵N-NaN₃ with an alkyne to form a triazole;

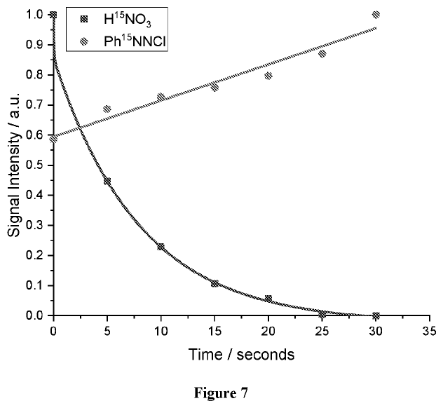

FIG. 7 illustrates that ¹⁵N NMR measurements allow the time course of a reaction to be quantified, in this case, the conversion of nitrite into a diazonium cation;

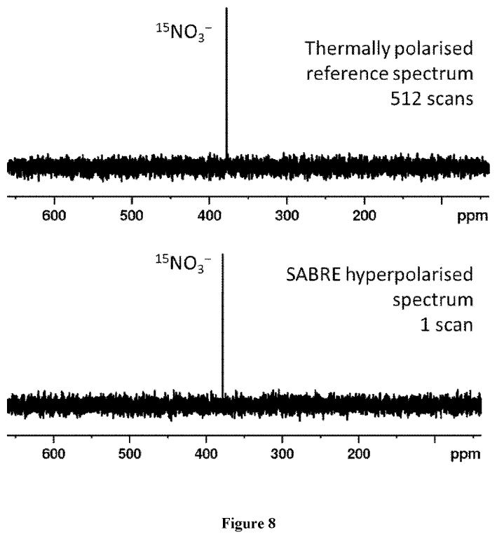

FIG. 8 illustrates the demonstration of NO₃^{- 15}N-hyperpolarisation under SABRE. Top trace showing a thermally polarised reference spectrum of Na¹⁵NO₃ recorded using 512 signal averages with the bottom showing the SABRE hyperpolarized spectrum recorded in a single scan; and

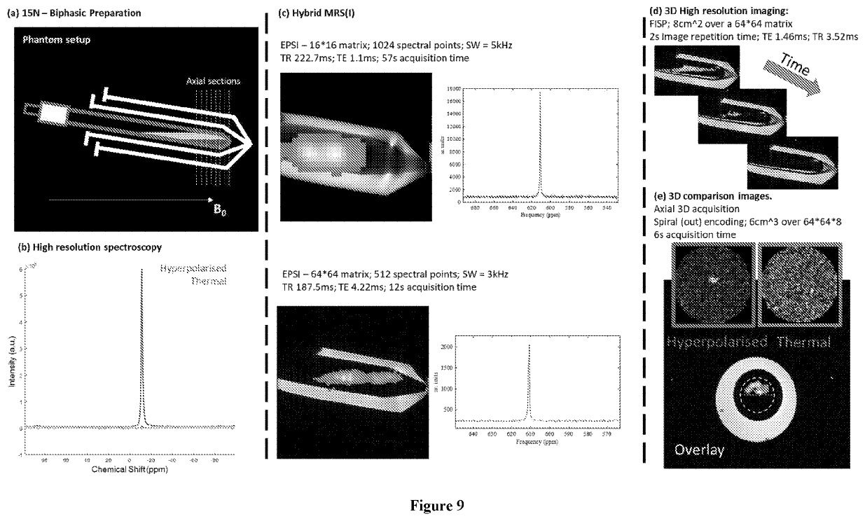

FIG. 9 illustrates the demonstration of ¹⁵N-hyperpolarisation aqueous bolus preparation under SABRE exemplified by NO₂⁻ (a) Picture of sample used in analysis; (b) demonstration of ¹⁵N NO₂⁻ hyperpolarisation in aqueous phase achieved using phase transfer catalysis via high-resolution 7 T spectrum; (c) two spatially resolved ¹⁵N-images showing the response for the upper aqueous phase at different spatial resolution; (d) time course map showing decay of signal as a function time after polarisation transfer; (e) thermally polarised comparison to demonstrate need for hyperpolarised response.

### EXPERIMENTAL PROCEDURES

### Materials

All of the experimental procedures associated with this work were carried out under nitrogen using standard Schlenk techniques. The solvents used were dried using an Innovative Technology anhydrous solvent system, or distilled from an appropriate drying agent under nitrogen. The catalyst precursor ([Ir(IMes)(COD)Cl](1) employed in this work was synthesized by established procedures according to literature methods. Deuterated chloroform (CDCl₃), deuterated water (D₂O), deuterated ethanol (EtOD) and pyrazine (2) were purchased from Sigma Aldrich and used as supplied.

### Example 1

Demonstration that an Active SABRE Catalyst Forms with Na¹⁵NO₂

For successful SABRE transfer to occur, the formation of a complex exhibiting spin-spin couplings between the bound substrate and p-H₂ derived hydride nuclei is required. Classically, this involves the reaction of a precatalyst (most commonly [IrCl(COD)(IMes)](1) (IMes=1,3-bis(2,4,6-trimethylphenyl)imidazolylidene)), with an excess of the selected substrate under a H₂ atmosphere. Complexes of type [Ir(H)₂(IMes)(sub)₃]Cl, when the substrate is a neutral N-heterocycle such as pyridine, meet this requirement. Consequently, our initial efforts targeted the synthesis of an active SABRE catalyst with bound NO₂⁻.

When Na¹⁵NO₂ (1 eq.) was added to a solution of [IrCl(COD)(IMes)](1, 5 mM) in methanol-d₄ the complete conversion to [Ir(¹⁵NO₂)(COD)(IMes)](2) at 298 K (Scheme 1) is observed. This change was readily evident as the ¹⁵N signal for free Na¹⁵NO₂ at δ_{N} 611.8 moved to δ_{N} 490.7 at 254 K. When complex 2 is exposed to a 3 bar pressure of H₂ at 254 K, the oxidative addition of hydrogen takes place to form [Ir(H)₂(¹⁵NO₂)(COD)(IMes)](3). This complex exhibits ¹H NMR resonances for its hydride ligands at δ_{H}−18.69 (hydride trans to ¹⁵NO₂⁻, ²J_{HN}=23.0 Hz and ²J_{HH}=−3.6 Hz) and δ_{H}−14.01 (hydride trans to COD, ²J_{HH}=3.6 Hz). Additionally, the signal for the bound ¹⁵NO₂⁻ ligand appears at δ_{N} 376.6. Hence there is a strong hydride-¹⁵N coupling in this material commensurate with SABRE.

Subsequently, this sample was warmed to 298 K for 20 minutes. This led to the formation of multiple hydride containing products; some of which display PHIP on exposure to p-H₂. Pleasingly, a hyperpolarised signal for free Na¹⁵NO₂ is observed in the ¹⁵N NMR spectrum after SABRE transfer at −5 mG. Whilst the ¹⁵N signal enhancement was just 134-fold, it confirms that the reversible binding of NO₂⁻ took place. However, when this sample was left at room temperature for >2 hours SABRE activity is lost. Hence, we sought to create alternative catalysts that would both improve the ¹⁵N signal enhancement level and be suitable for repeated measurement over long periods. Co-ligands have been used to achieve stability in conjunction with weakly binding ligands,^{40-41, 73} reduced spin dilution^{42, 74-75} and hydride ligand chemical, rather than magnetic, inequivalence.⁷⁶ We hypothesized that the addition of a suitable co-ligand with NaNO₂ could therefore ameliorate low complex stability whilst maintaining NO₂⁻ coordination and strong ¹⁵N-hydride ligand couplings and set out to prove this. Thus, a sample containing [IrCl(COD)(IMes)](1, 5 mM), Na¹⁵NO₂ (5 eq) and pyridine (3 eq.) was interrogated by NMR spectroscopy. The initial formation of [Ir(¹⁵NO₂)(COD)(IMes)](2) was indicated. Hence, nitrite outcompetes pyridine for Ir(COD)(IMes)⁺. Subsequently, exposing this sample to 3 bar H₂ at 254 K led to the formation of neutral [Ir(H)₂(NO₂)(IMes)(η¹-COD)(pyridine)](4_{A}) with diagnostic hydride resonances at δ_{H}−14.00 and −18.77 that share a ²J_{HH} coupling of −3.3 Hz; the latter resonance also exhibits a ²J_{NH} of 23.1 Hz. The bound resonance for NO₂⁻ appears at δ_{N} 476.1. We note, that known [Ir(H)₂(IMes)(η¹-COD)(pyridine)₂]Cl (5^{A}) forms alongside 4a in a 1:4 ratio. After warming the sample for 1 h at room temperature, further reaction, to form two additional hydride containing products, takes place. Of these, [Ir(H)₂(¹⁵NO₂)(IMes)(pyridine)₂](6_{A}), with characteristic hydride peaks at δ_{H}−21.24 and −22.45, dominates. The former resonance exhibits a ²J_{NH} splitting of 28.3 Hz, and both show ²J_{HH} couplings of −7.5 Hz. The minor product proved to be Na[Ir(H)₂(¹⁵NO₂)₂(IMes)(pyridine)](7_{A}). It yields hydride resonances at δ_{H}−22.02 (²J_{NH}=28.5 Hz) and −23.01 with mutual 2J_{HH} splittings of −7.6 Hz. Interestingly, no evidence for the formation of Iris pyridine containing [Ir(H)₂(IMes)(pyridine)₃]Cl, is observed.⁷⁷

Unlike the complexes formed in the absence of pyridine, the pyridine derived NO₂⁻ complexes 6_{A} and 7_{A} proved stable when left at room temperature for >24 hours and were therefore suitable for assessment of their SABRE performance. When the ratio of Na¹⁵NO₂ to pyridine was set to 5:3, the ratio of 6_{A} to 7_{A} in solution proved to be 85:15. Addition of excess Na¹⁵NO₂ (25 eq), whilst maintaining the pyridine concentration, only moderately shifted the equilibrium between 6_{A} and 7_{A} to 80:20 thereby confirming neutral [Ir(H)₂(¹⁵NO₂)(IMes)(pyridine)₂](6_{A}) is the thermodynamic product.

### Example 2

SABRE Assessment of [Ir(H)₂(¹⁵NO₂)(IMes)(py)₂](6_{A}) and Na[Ir(H)₂(¹⁵NO₂)₂(IMes)(A)](7_{A}) Activity

In order for effective SABRE, the lifetime of the active catalyst must match with the propagating couplings and a level anti-crossing condition be met.^{43-44, 46} For 6_{A} and 7_{A}, the ²J_{NH} couplings have been measured to be 28.3 and 28.5 Hz and an optimum polarisation transfer field (PTF) on the order of mG will be needed.^{54, 58-59} Therefore, to assess the SABRE performance of 6_{A} and 7_{A}, a series of shake and drop measurements were undertaken using a mu-shield⁷⁸ to attenuate the earth's field by a factor of 300. These involved first exposing an NMR tube equipped with a J. Youngs Tap containing a solution of [IrCl(COD)(IMes)](1, 5 mM), Na¹⁵NO₂ (5 eq.) and pyridine (4 eq.) in methanol-d₄ (0.6 mL) to H₂ (3 bar) for 1 h to form an 85:15 ratio of 6_{A} to 7_{A} in solution. Subsequently, the H₂ atmosphere was replaced with p-H₂ (3 bar) and the sample shaken for 10 seconds in the mu metal shield. After shaking, the sample was transferred into the 9.4 T detection field and a ¹⁵N NMR spectrum recorded.

Analysis of this NMR spectrum revealed that the free ¹⁵N signal of Na¹⁵NO₂ was now 878-fold larger than that of the corresponding thermally polarised NMR spectrum at 9.4 T; corresponding to a 0.29% ¹⁵N polarisation level. SABRE transfer to the ¹⁵N of unlabelled pyridine at this low field was also observed, and a 172-fold signal gain quantified for its resonance at δ_{N} 301. The ¹⁵N NMR signals of the coordinated NO₂ ligands were also readily visible at δ_{N} 511.28 (J_{HN}=28.3 Hz) for 6_{A} and at δ_{N} 509.7 (J_{HN}=28.3 Hz) for the NO₂ in the equatorial position and at δ_{N} 483.7 for the ligand in axial position of 7_{A}. Repeating the experiment after polarisation transfer at 70 G and subsequently recording a ¹H NMR spectrum revealed PHIP enhanced hydride resonances for 6_{A} and 7_{A}. SABRE hyperpolarisation was also quantified for the ¹H resonances of free pyridine as ˜230, 60 and 150-fold for its ortho, meta and para positions respectively. No evidence for a PHIP enhanced hydride resonance for [Ir(H)₂(IMes)(py)₃]Cl at δ_{H}−22.7 was observed. We conclude therefore that ¹⁵NO₂⁻ sensitisation is possible through the action of this co-ligand supported catalyst.

### Example 3

Effect of Polarisation Transfer Field on Level of ¹⁵N NMR Signal Gain in Na¹⁵NO₂

In order to improve the levels of signal gain a more precise polarisation transfer field needs to be used. To investigate this effect, a sample containing [IrCl(COD)(IMes)](1, 5 mM), Na¹⁵NO₂ (5 eq.) and pyridine (4 eq.) in methanol-d₄ (0.6 mL) was exposed to p-H₂ (3 bar) and polarisation transfer fields from +10 mG to −10 mG were deployed; these were created by a solenoid located within a mu-metal shield. A profile of the resulting SABRE enhanced resonance for Na¹⁵NO₂ is presented in FIG. 1. The highest signal enhancements were observed when the polarisation transfer field was nominally +5 mG or −3 mG with gains of 1948 and 2054-fold respectively. More precise probing of the polarisation transfer field around these maxima revealed that improvement could be achieved by using a −3.5 mG value. At this field a 2329-fold signal gain was quantified through subsequent measurement at 9.4 T which corresponds to a ¹⁵N polarisation level of 0.77%.

### Example 4

### Effect of Co-Ligand on SABRE Catalysis

In order to form 6_{A} and 7_{A}, ¹⁵NO₂⁻ must out-bind the stabilising co-ligand pyridine. This means that the SABRE processes should be sensitive to the identity of this co-ligand; this behaviour has recently been observed during the SABRE polarisation of sodium pyruvate bysulfoxides,³⁹ although there are other examples.^{41, 79-80} Additionally, isotopic labelling of these co-ligands has been shown to reduce the number of acceptor spins at the metal centre and modulate relaxation.^{42, 81-82} Therefore, a range of co-ligands were examined in order to see if it was possible to improve the polarisation levels in free Na¹⁵NO₂, as detailed in FIG. 2.

In each case, samples containing [IrCl(COD)(IMes)], Na¹⁵NO₂ (25 eq.) and the co-ligand (A-H, 4 eq.) were first exposed to 3 bar H₂ at 298 K for 1 hour to form the corresponding complexes 6 and 7. Subsequently, the sample was exposed to 3 bar p-H₂, in a −3.5 mG field, prior to rapid insertion into the 9.4 T detection field. Under these conditions, pyridine (A) now yields a 2329-fold signal enhancement (0.77% ¹⁵N polarisation). ¹⁵N labelled pyridine (A-¹⁵N) was then examined, and this reduced the signal enhancement level for Na¹⁵NO₂ to 2107-fold. This is likely to be due to the increase in spin dilution associated by increasing the proportion of spin-½ nuclei. The resonance for free ¹⁵N-pyridine at δ_{N} 301 now exhibits a lower signal gain of 1558-fold. In contrast, the use of pyridine-d₅ (A-d₅) improves the SABRE hyperpolarisation for Na¹⁵NO₂ as the new enhancement level is now 3007-fold. As expected, all the pyridine isotopologues yield complexes 6 to 7 in an 85:15 ratio. This ca. 30% improvement, when compared to the undeuterated ligand, is likely to be due to slower relaxation in the active catalyst.

In order to further modulate the co-ligand, other pyridyl derivatives having differing steric and electronic properties were examined. 2,6-Lutidine (B), which until recently was inaccessible to SABRE,⁸³⁻⁸⁴ was chosen as its ortho methyl groups hinder binding to the metal centre, which might promote ligand loss. When B is employed in conjunction with Na¹⁵NO₂, an increase in SABRE polarisation level is overserved when compared to pyridine. Interestingly, the ratio of 6_{B} to 7_{B} is now 95:5, but slow activation means [Ir(H)₂(NO₂)(η¹-COD)(B)](4_{B}, c.f scheme 1) is visible with hydride resonances at δ_{H}−18.78 (²J_{NH}=22.6 Hz and 2J_{HH}=6 Hz) and −14.18 (2J_{HH}=6 Hz); at this stage, it is observed in a 1:1 ratio with 6_{B}. Unfortunately, when this sample is left under a 3 bar atmosphere of H₂ for 72 h, sample degradation and the formation of multiple hydride containing complexes is noted. Hence, B is unable to provide the long term stability needed to reliably probe its behaviour.

The use of electron deficient methyl 4,6-d₂-nicotinate (C), which has been shown to exhibit ¹H polarisation levels of ca. 60%,^{42, 63} was found to decrease the signal enhancement of Na¹⁵NO₂ to 1894. The formation of 7_{C} is promoted by this change as the ratio of 6_{C} to 7_{C} became a 1:2. In contrast, electron rich dimethylamino pyridine (D, DMAP) forms 6_{D} in a 17:1 ratio with 7_{D}. Additionally, a significantly improved 10313-fold ¹⁵N signal enhancement is observed for Na¹⁵NO₂ which corresponds to the creation of a 3.4% ¹⁵N polarisation level.

Non-heterocyclic ligands can also be utilized for SABRE. As such, amine ligands have been shown to be able to form stable SABRE catalysts and are effective agents for SABRE-Relay polarisation transfer.^{81-82, 85-87} When utilized as a co-ligand for the hyperpolarisation of Na¹⁵NO₂, benzylamine-d₇ (E-d₇) led to a ¹⁵N signal gain of 2070-fold. The two hydride containing complexes 6_{E} and 7_{E} were formed under these conditions in a ca. 1:1 ratio with hydride resonances at δ_{H}−22.10 and −23.40 and δ_{H}−22.36 and −22.72 respectively. When aniline (F) was used as the co-ligand, a 3322-fold signals gain for Na¹⁵NO₂ was quantified. In this sample, 6_{F} now dominates.

Similarly, sulfoxides have proven to be efficacious for the hyperpolarisation of sodium pyruvate and weakly coordinating substrates.^{39-40, 79, 88} The co-ligand DMSO-d₆ (G) gave a 6270-fold signal enhancement for Na¹⁵NO₂. Interestingly, whilst Na[Ir(H)₂(¹⁵NO₂)₂(IMes)(DMSO-d₆)] as 7_{G} is now dominant in solution, a second isomer of (8_{G}), where the two ¹⁵NO₂ ligands lie cis to one another and trans to hydride is now observed. This complex gives rise to a single hydride resonance at δ_{H}−22.32 where J_{NHcis}+J_{NHtrans} is 27.6 Hz. The ¹⁵NO₂ resonance of 8_{G} appears at δ_{H} 502.0. Isomer 6_{G} is detected as a minor species, with the ratio of 6_{G}:7_{G}:8_{G} in solution being ˜1:9:5. Finally, acetonitrile⁸⁹ gave a 2029-fold ¹⁵N signal gain and the neutral complex [Ir(H)₂(¹⁵NO₂)(IMes)(acetonitrile)₂](6_{H}), with hydride resonances at δ_{H}−22.66 (²J_{HH}=26.7 Hz and ²J_{HH}=−7 Hz) and −21.77 (²J_{HH}=−7 Hz) was the only complex observed.

### Example 5

Identifying the Optimum DMAP (D): Na¹⁵NO₂ Ratio

The highest ¹⁵N polarisation level for Na¹⁵NO₂ was achieved with the DMAP co-ligand. Interestingly, this ligand yielded the highest concentration of isomer 6. We postulated that the concentration of 6D in solution could be further manipulated by changing the number of equivalents of D in relation to [IrCl(COD)(IMes)](1) and Na¹⁵NO₂. Therefore, a series of samples were prepared with between 3-20 eq. of D relative to 1. After activation, they were exposed to 3 bar p-H₂ whilst located in a −3.5 mG polarisation transfer field. The resulting signal enhancements at 9.4 T are shown in FIG. 2.

When 3 equivalents of D (with respected to iridium) is utilised, a 9086-fold signal enhancement is observed with the corresponding 6_{D}:7_{D} ratio being 8:1. Increasing the concentration of DMAP to 4 equivalents improved the signal gain seen at 9.4 T to 11019-fold. The ratio of complex 6_{D}:7_{D} also increased to 17:1. Further incremental increases in DMAP concentration, to 6, 8 and 10 eq., gave signal enhancements of 12036, 12079 and 11888-fold respectively. The ratio 6_{D}:7_{D} was now 24:1 in all three samples. At higher loadings of D, the formation of [Ir(H)₂(IMes)(D)₃]Cl is observed, as a single hydride resonance at δ_{H}−23.00. Clearly, this catalyst does not transfer hyperpolarisation to Na¹⁵NO₂ and hinders the overall ¹⁵N signal gain due to consumption of p-H₂. Therefore, we conclude that the optimum DMAP level lies between 6-10 equivalents with respect to iridium and this results in 6_{D} being the dominant species in solution.

### Example 6

### Synthesis and Utilization of DMAP-d₂ for SABRE

Deuteration of ligands within the active catalyst can provide a route to improved polarisation transfer due to reduced spin-dilution and an increased lifetime of the hyperpolarised state.^{42, 75-76, 89-90} We postulated that deuteration of the ortho protons in D to give DMAP-d₂ may lead to further improvements in the ¹⁵N polarisation level in Na¹⁵NO₂. Therefore, DMAP-d₂ was synthesized via H/D exchange from DMAP in D₂O under microwave irradiation as reported in the literature.⁹¹ Preparation of a sample containing [IrCl(COD)(IMes)](5 mM), DMAP-d₂ (6 eq.) and Na¹⁵NO₂ (25 eq.) in methanol-d₄ and exposure to 3 bar p-H₂ at a polarisation transfer at −3.5 mG led to a signal gain of 13811 after interrogation at 9.4 T (4.56% ¹⁵N polarisation level). The corresponding value with protio DMAP is 12036, and hence introducing the ²H can be concluded to be beneficial to the SABRE outcome. Interesting, no significant change in the T₁ value of the hyperpolarised ¹⁵NO₂ signal was seen and we conclude that the signal improvement results mainly from reduced spin-dilution around the active centre.

### Example 7

Effect of NHC Identity on the Efficiency of Na¹⁵NO₂ Polarisation

Aiming to improve the polarisation outcome still further, a study of the effect of the NHC ligand was completed in conjunction with DMAP-d₂. Previously, we have shown how manipulation of the steric and electronic properties of this ancillary ligand can result in improved ¹H, ¹³C and ¹⁵N signal enhancements due to changes in the rate of ligand exchange.⁶³ Having first noted that dissociation of the ¹⁵NO₂⁻ ligand bound in the equatorial plane is slower than that which would be predicted to be optimum, we sequentially increased the steric bulk of the NHC (quantified by the magnitude of % BurV⁹²⁻⁹³) to drive ligand exchange. On moving from the IMes ligand (% BurV 31.2) to SIMes (32.7) we saw a 14628-fold signal gain which is a slight improvement from the 13811-fold signal gain previously observed for IMes. IPr (33.6) and SIPr (35.7) both also led to increased signal enhancements of 15799 and 17149-fold. However, the best result was obtained for IPent which gave a 20337-fold signal gain and has the highest % BurV of 43.4.

Next our focus turned to the electronic properties of the NHC ligand. As expected, electron deficient IMes^{Cl}, which has chloro substituents on the imidazole ring, reduced the signal enhancement to just 5471. Introducing methyl groups on the imidazole ring showed minimal effect when compared to IMes (13336-fold vs. 13811-fold respectively). However, introduction of a single —NMe₂ group increased the signal enhancement level to 16427-fold at 9.4 T.

To combine the steric and electronic effects, we utilized the ligand IPr^{NMe2}, which has previously proven to be effective for Buchwald-Hartwing amination catalysis,⁹⁴⁻⁹⁵ to form the precatalyst [IrCl(COD)(IPr^{NMe2})]. This catalyst gave the highest ¹⁵N signal enhancement for Na¹⁵NO₂ of 21967-fold at 9.4 T which is equivalent to 7.2% polarisation. These results are summarised in FIG. 3.

### Example 8

Effect of Na¹⁵NO₂ Concentration on Signal Enhancement

A series of samples were interrogated that contained varying concentration of Na¹⁵NO₂ that differed from the standard 25 eq. that had been employed so far in this patent but utilized the optimum catalyst [IrCl(COD)(IPr^{NMe2})](5 mM) and DMAP-d₂. Reducing the substrate concentration to 10 eq. with respect to iridium increased the signal enhancement to 36629-fold. With just 4 eq. of Na¹⁵NO₂ a signal enhancement of 62470-fold was quantified at 9.4 T which corresponds to 20.6% ¹⁵N polarisation. Conversely increasing the substrate loading to 50 eq. reduced the signal gain to 10382 (3.17%), however, the final signal to noise level was improved. If the concentration of [IrCl(COD)(IPr^{NMe2})] is reduced to 0.25 mM whilst maintaining 1:4 molar ratio with Na¹⁵NO₂ the ¹⁵N polarisation level further increases to 28.42%. This phenomenon is likely to be due to effectively increasing the excess of p-H₂ relative to substrate and catalyst and has been observed previously.^{56, 63}

### Example 9

### Detection of Unlabelled NaNO₂

Given the high signal gains obtained for Na¹⁵NO₂⁻, we wished to test the analogous SABRE hyperpolarization effect using NaNO₂ where the ¹⁵N label was present at natural abundance. When such a sample, containing 20 mM of NaNO₂⁻, was examined with the [IrCl(COD)(IPr^{NMe2})](5 mM) and DMAP-d₂ (6 eq), a ¹⁵N signal was easily seen whose signal enhancement was 115592-fold at 9.4 T; this corresponds to a 38.1% P_{15N} level.

### Example 10

### Effect of 15-Crown-5 and Utilisation of Biphasic Catalysis

Unfortunately, the ionic nature of NaNO₂ acts to limit its solubility in the organic solvents typically employed for SABRE catalysis; it has a moderate solubility in methanol, however, it is sparingly soluble in other primary alcohols and insoluble in most apolar solvents. In an attempt to increase methanol-d₄ solubility, the macrocycle 15-crown-5 was added, which has a high chelating affinity for Na⁺.⁹⁶⁻⁹⁷ SABRE transfer was therefore undertaken on a sample containing [IrCl(COD)(IMes)](5 mM), Na¹⁵NO₂ (25 eq.), DMAP (6 eq.) and 15-crown-5 (25 eq.) in methanol-d₄. This led to a ¹⁵N signal enhancement of 12044-fold being obtained at 9.4 T. This corresponds to a ¹⁵N polarisation level of 3.97%. It reflects a 10% improvement over the analogous measurement when 15-crown-5 is not present. Interestingly, the ratio of 6_{D} to 7_{D} was now 99:1 as opposed to 91:9 in the absence of 15-crown-5. Using the optimised catalyst and co-ligand ([IrCl(COD)(IPr^{NMe2})](5 mM), Na¹⁵NO₂ (25 eq.), DMAP-d₂ (6 eq.)) the effect of 15-crown-5 is less pronounced with the ¹⁵N signal gain improving from 21967-fold to 23114-fold.

When an NMR sample containing [IrCl(COD)(IMes)](5 mM), Na¹⁵NO₂ (25 eq.) and D (6 eq.) was prepared in dichloromethane-d₂ (0.6 mL), the impact of insolubility of Na¹⁵NO₂ was immediately evident. After sonication for 30 mins, the sample was exposed to H₂ (3 bar). Interrogation by NMR spectroscopy revealed that the only hydride containing species present in solution was [Ir(H)₂Cl(IMes)(DMAP)₂]. However, when an analogous sample was prepared containing 15-crown-5 in a 1:1 ratio with Na¹⁵NO₂⁻, a different hydride containing complex formed. Its hydride resonances appear at δ −22.66 (²J_{HN}=27.5 Hz and 2J_{HH}=−7 Hz) and δ −23.00 (²J_{HH}=−7 Hz) and match those of 6_{D}. After SABRE transfer in a −3.5 mG field, a 3586-fold signal enhancement was observed at 9.4 T for the free ¹⁵NO₂⁻ resonance δ_{N} 618. Warming this sample to 308 K prior to polarisation transfer significantly improved the signal gain to 7248-fold and indicates that slow ligand exchange limits the polarisation level attained. However, warming further to 323 K yielded no further increase. Using the electron rich and sterically encumbered pre-catalyst [IrCl(COD)(IPr^{NMe2})], also yielded improved polarisation transfer as an 8149-fold signal gain is seen at 9.4 T. Warming this sample further, however, had no benefit. Hence, we have demonstrated how significant polarisation levels for ¹⁵NO₂⁻ can be achieved in dichloromethane-d₂ by the addition of 15-crown-5.

### Example 11

Producing Hyperpolarised NO₂⁻ in Water

For biological applications, it is desirable to produce hyperpolarised NO₂⁻ in water. Unfortunately, 6_{A} did not form when the analogous reaction was screened in this solvent. However, it could be obtained via its prior formation in methanol, solvent removal and replaced by D₂O. Preforming 6_{A} in methanol-d₄ prior to removing the solvent and replacing it with D₂O was also unsuccessful. One further other way to achieve this outcome is to use a biphasic⁹⁸ dichloromethane-d₂ approach which benefits from the fact the catalyst is not present in the aqueous layer.⁹⁹⁻¹⁰⁰ A sample containing [IrCl(COD)(IMes)](5 mM), Na¹⁵NO₂ (25 eq.) and DMAP (6 eq.) and 15-crown-5 (25 eq.) in dichloromethane-d₂ (0.3 mL) was prepared and exposed to H₂ (3 bar) to form the active catalyst. D₂O (0.3 mL) was then added under a nitrogen atmosphere. After SABRE transfer at −3.5 mG and phase separation, two hyperpolarised signals were seen in the result in the corresponding ¹⁵N NMR spectrum for Na¹⁵NO₂ at δ_{N} 618 and δ_{N} 609. These peaks had relative intensities of 1:70 and were assigned to Na¹⁵NO₂ dissolved in the dichloromethane-d₂ and D₂O phases respectively by comparison with data from independent solutions. The ¹⁵N signal gain in the D₂O layer was estimated to be 4667-fold, assuming all of the Na¹⁵NO₂ was present in it; this underestimates the real value. As 15-crown-5 can also play a role as a phase transfer catalyst,¹⁰¹ a further 25 eq. was added to the sample and this proved to increase the signal enhancement level to 13794-fold. Further additions of 15-crown-5 did not improve on this, however, but warming the sample to 308 K resulted in a 26327-fold signal gain at 9.4 T. This is equivalent to an 8.69% polarisation level in Na¹⁵NO₂. Hence, we have created a simple route to hyperpolarised Na¹⁵NO₂ in water. The level of signal gain compares favourably with the <1% reported with DNP.¹² See FIG. 9.

### Example 12

Assessment of Na¹⁵NO₂ Relaxation Rates

The DNP hyperpolarised Na¹⁵NO₂ is reported to have a T₁ of 14.8 s in D₂O.¹² We used a low-tip angle approach to assess the T₁ of our SABRE polarised product at 9.4 T. It was found to be 16.45 s. This value was also probed using an automated hyperpolarisation device under reversible flow, after first conducting the SABRE process at −3.5 mG, prior to turning off the p-H₂ supply and holding the sample in a defined magnetic field for a period of time, prior to transfer to 9.4 T to acquire a spectrum. Repeating this process for varying time points, enables the effective low field T₁ value to be calculated. This was undertaken for samples stored in the mu-metal shield (ca. 300-fold shielding) and a −3.5 mT. The new T₁ values were 14.9 s and 11.2 s respectively. These values suggest that there will be sufficient time to use ¹⁵NO₂⁻ synthetically to create other hyperpolarised products as 3×T₁ is available before the signal vanishes. Interestingly, as the T₁ values for ¹⁵N nuclei can dramatically be extended at appropriate magnetic fields reaction time of many minutes may be possible.

### Example 13

Conversion of Hyperpolarised Na¹⁵NO₂ to a Diazonium Via NO⁺

The Sandmeyer reaction rapidly converts arylamines to an arylhalide via a diazonium salt intermediate.¹⁰² Since the first reported example in 1884,¹⁰³ it has become a mainstay of organic chemistry and many related reactions have been discovered.¹⁰⁴ Classically, it utilizes either stoichiometric or catalytic amounts of copper halides, although, a number of metal free variants are known.¹⁰⁵⁻¹⁰⁷ The formation of the diazonium salt intermediate proceeds via nitrous acid addition, which is formed in situ from the reaction of NaNO₂ and a strong acid. We sought to follow a diazotization reaction by SABRE hyperpolarised ¹⁵N NMR spectroscopy. Therefore, we created hyperpolarised Na¹⁵NO₂ using the previously optimized conditions ([IrCl(COD)(IMes)](5 mM), DMAP (30 mM), Na¹⁵NO₂ (125 mM) in methanol-d₄ (0.6 mL)) prior to adding a solution of aniline (150 mM) and conc. HCl (100 μL) in methanol-d₄ (100 μL). The NMR tube was immediately transferred to the spectrometer and interrogated using a T₁ corrected variable flip angle pulse sequence. It took between 3 and 5 s to start the measurements and hyperpolarised signals indicative of nitrous acid (H¹⁵NO₂, δ_{N} 563) and for phenyl diazonium chloride (δ_{N} 314) and ortho-¹⁵N₂(δ_{N} 309) were evident in these NMR spectra. Their identity was confirmed by their independent synthesis, and comparison to literature data.¹⁰⁸ Over the course of 30 s, the signals for H¹⁵NO₂ vanished. See FIG. 4.

Upon repeating this process using aniline-¹⁵N, reaction monitoring revealed the detection of hyperpolarised responses for both of the ¹⁵N centres in the diazo product, at δ_{N} 315.0 and 232.6 which are consistent with values reported in the literature.¹⁰⁹ This happens even though aniline itself was not hyperpolarised. Consequently, efficient polarisation transfer takes place during the reaction at low field within the coupled spin pair. As a control, we exposed a sample of phenyl diazonium chloride and the catalyst to p-H₂ at −3.5 mG and noted no hyperpolarised ¹⁵N resonances result. Consequently, all the hyperpolarised signals seen during this reaction originate from the initially hyperpolarised Na¹⁵NO₂.

### Example 14

Reactions of Hyperpolarised ¹⁵N₂-Phenyl Diazonium Chloride and Therefore the Creation of Hyperpharmaceuticals Via NO₂

The phenyl diazonium chloride product proved to have hyperpolarised T₁ values for the ¹⁵N₁ and ¹⁵N₂ nuclei of 29.4 and 39.2 s respectively at 9.4 T. Additionally, it proved to be relatively stable under these reactions conditions with only limited decomposition to hyperpolarised ¹⁵N_{2 (g)} (δ_{N} 309) being observed. This meant we could explore further the reactivity of the diazonium salt. It is known that such salts liberate N₂ under photochemical or transition metal catalysed processes.¹¹⁰⁻¹¹¹ Under our hyperpolarised regime, addition of CuI saw the rapid conversion of the phenyl diazonium chloride into N₂ which is visible in solution through a signal at δ_{N} 308. It was also treated with NaN₃ to form hyperpolarised phenyl azide. This material yields ¹⁵N NMR resonances at δ_{N} 242.2 and 90.1 that share a common ²J_{NN} of 13.8 Hz. According to the literature, this reaction could proceed via a linear and/or a cyclic intermediate, which would deliver 5 and 3 distinct ¹⁵N signals respectively.¹¹²⁻¹¹⁴ It interestingly we detect this transient species through signals at δ_{N} 356.8 and 298.2 (²J_{NN}=16.7 Hz) for the site connected to the C₆H₅ ring which we assign to this product. Upon repeating this study with 1-¹⁵N NaN₃, these two signals gain further complexity and appear alongside one other at δ_{N} 387.3 (d, 17 Hz). These additional features are reflective of the two possible isotopologues that can result from ¹⁵N₁-N₃⁻ addition to form a cyclic intermediate, which place a Ph-¹⁵N next to two ¹⁵N groups (a triplet at δ_{N} 298.6 with 17 Hz is seen for it alongside a doublet of 17 Hz at δ_{N} 356.9) or one (a doublet at δ_{N} 298.6 of 17 Hz is now seen, alongside a further triplet at 356.9 of 17 Hz and a doublet at δ_{N} 387.3 (d 17 Hz). Hence all three signals for this cyclic intermediate have been detected. We note its conversion to phenyl azide (Ph-¹⁵N═¹⁵N⁺═¹⁵N⁻ and Ph-¹⁵N═¹⁵N⁺≡N⁻) proceeds rapidly at 298 K and the signals for this product appear δ_{N} 90.3, 242.5 and 232 with apparent T₁ values of 56, 192 and 101 s at 9.4 T, all respectively. See FIGS. 5 and 7.

These long T₁ values enable the creation of strongly hyperpolarized and reactive phenyl azide. When the reactive alkyne, (1R,8S,9s)-bicyclo[6.1.0]non-4-yn-9-ylmethanol,¹²¹ is added to this sample as a third synthetic step, reaction to form the corresponding triazole occurs. Despite the corresponding ¹⁵N signals for this product having sub 10 s T₁ values, its formation is readily indicated in the associated hyperpolarized ¹⁵N NMR measurements (δ_{N} 335.4 and 255.3 with a mutual ²J_{NN} 12.8 Hz). As copper-free click-chemistry is used widely for bioconjugation with nuclei acids we expect such measurements to help in the optimization of pharmaceutical preparations and/or in vivo detection.¹²²⁻¹²³

These data (see FIG. 6) have clearly illustrated the successful examination of a multistep reaction as it proved possible to simultaneously see ¹⁵N signals for the phenyl diazonium salt, the pentazole intermediate and phenyl azide or the pentazole intermediate, phenyl azide and the triazole. The detection of such species can be used in conjunction with the optimisation of a synthetic procedure or to create a hyperpharmaceutical.

### Example 15

Conversion of Hyperpolarised Na¹⁵NO₂ to ¹⁵N₂ Through Reaction with ¹⁵NH₄Cl/HCl

N₂ gas spontaneously forms from the diazonium salts of primary amines. As ¹⁵NH₄Cl is readily available we monitored its reaction with Na¹⁵NO₂ and as expected see strong signals for ¹⁵N₂ in solution (see FIG. 6). We have therefore detailed two approaches that ultimately are expected to lead top-N₂^{57, 115}.

### Example 16

### Utilization of ¹⁵N Hyperpolarised Azide, Amines and Ammonia as Probes of Reactivity and Therefore the Creation of Hyperpharmaceuticals

The SABRE hyperpolarisation of NH₃ and amines, such as benzylamine, and their use in SABRE-Relay has been extensively reported.^{81-82, 85-87} Additionally, ammonia and amines have been used as a co-ligand that leads to improved SABRE catalysis.^{68, 116} The ¹⁵N polarisation of benzylamine-¹⁵N (E-¹⁵N) is reported to be ca. 800-fold at 9.4 T. This involves [Ir(H)₂(IMes)(E-¹⁵N)₃]Cl in dichloromethane-d₂ solution.⁸⁵ We restudied this process in order to improve the SABRE outcome and provide access to a further functional group to demonstrate hyperpolarised reactivity screening. Using the same conditions as previously reported ([IrCl(COD)(IMes)](5 mM), benzylamine-¹⁵N (E-¹⁵N, 7 eq.)) we determined that optimal SABRE transfer occurs at −4 mG. At this field a 7751-fold signal enhancement was achieved at 9.4 T. As the rate of benzylamine dissociation from [Ir(H)₂(IMes)(E-¹⁵N)₃]Cl in dichloromethane-d₂ is slow^{45, 86} we found that warming the sample to 308 K further improved the enhancement level to 11211-fold which corresponds to 3.7% ¹⁵N polarisation; it has a 14 s T₁ at 9.4 T in the absence of the catalyst, and 12.8 s when it is present.

As amines show a wide range of reactivity, we exemplified the utilisation of hyperpolarised E-¹⁵N as a synthon for amidation, sulfamidation and imine formation. This resulted in the ¹⁵N detection of the products shown in FIG. 6. Their identity was verified by independent synthesis.

Specifically, the addition of trifluoroacetic anhydride to hyperpolarised E-¹⁵N led to the formation and detection of N-benzyl-trifluoroacetamide-¹⁵N in the resulting ¹⁵N NMR spectrum through a signal at δ_{N} 116.4. Similarly, triflic anhydride reacted to yield the analogous sulfonamide with a resonance at δ_{N} 88.6. Finally, addition of benzaldehyde to E-¹⁵N produced the imine condensation product as evident by a peak at δ_{N} 327.7.

Ammonia is also widely used in synthetic chemistry and we sought to exemplify its hyperpolarised reactivity. Due to ¹⁵NH₃(g) being expensive and difficult to handle, we pursued the use of an alternative ammonia source. By using a 1:1 mixture of ¹⁵NH₄Cl/KOtBu we were able to form the active SABRE catalyst [Ir(H)₂(IMes)(¹⁵ND₃)₃]Cl in methanol-d₄. After polarisation transfer at −4 mG, a 3268-fold ¹⁵N signal gain was quantified. However, over the course of ca. 1 h, the signal enhancement diminishes when the SABRE process is repeated. In contrast, the use of ¹⁵NH₄OH (available as a ¹⁵N solution in H₂O) yielded the same active catalyst, but the sample is now stable >24 h. The ¹⁵N signal enhancement is also slightly improved to 3765-fold. Changing the NHC ligand proved to have a modest effect on SABRE efficacy and warming the sample to 308 K now improved the signal gain to 4521-fold. However, dramatic improvements result with a co-ligand. Whilst the co-ligands DMSO-d₆, CD₃CN, NO₂⁻ and DMAP were explored, pyridine-d₅ proved to give the highest signal gain of 15145-fold (5.0% polarisation). The ¹⁵N T₁ value for ¹⁵ND₃ at 9.4 T proved to 37 s which means the wide over which a reaction can be examined is substantial. Protonation of ¹⁵ND₃ with DCl in D₂O led to the detection of hyperpolarised ¹⁵ND₄⁺ as a signal δ_{N} 15.93 with resolved ¹⁵N-D scalar couplings, J_{ND}, of 10.8 Hz and a hyperpolarised T₁ of 33.6 s.

The SABRE hyperpolarization of the versatile synthon 1-¹⁵N NaN₃ itself, using the co-ligand strategy with DMAP and 1 also proved successful. The reaction was found to proceed to form [Ir(H)₂(DMAP)₂(IMes)(¹⁵N═N=N)] which exhibits hydride signals at δ_{H}−23.1 (²J_{HH}=8 Hz) and δ_{H}−25.0 (²J_{HH}=8 Hz and ²J_{NH}=8 HZ) alongside [Ir(H)₂(DMAP)₃(IMes)]Cl (δ_{H}−22.8). SABRE transfer at −3.5 mG yielded 3.2% hyperpolarization of the N₃⁻ signal at δ_{N} 95.7. A hyperpolarised solution of NaN₃ was then reacted directly with (1R,8S,9s)-bicyclo[6.1.0]non-4-yn-9-ylmethanol to form the triazole. Under these conditions, a single hyperpolarized ¹⁵N response for the product was visible at δ 321.3 as expected. The screen of this reagents reactivity has also been exemplified. We note its use in the formation of N₂ in air bags, so using it as a simple solid state source of hyperpolarised N₂ is feasible.

### Example 17

SABRE Hyperpolarisation of Na¹⁵NO₃⁻

In contrast to nitrite, nitrate is usually non-coordinating, however, there are examples of it functioning as a weak monodentate or bidentate ligand.^{27, 117-121} To further explore SABRE's use as a tool to polarise materials featuring in the nitrogen cycle we explored the SABRE hyperpolarisation of Na¹⁵NO₃. As expected, in the absence of a co-ligand no active SABRE catalyst formed in the reaction between [IrCl(COD)(IMes)] and Na¹⁵NO₃⁻ under a H₂ atmosphere (3 bar) in methanol-d₄. We screened a number of co-ligands (DMAP, 2-picoline, DMSO-d₆, DPSO or CD₃CN) and saw no evidence for the ¹⁵N polarisation of Na¹⁵NO₃. In each case, the dominant hydride containing species in solution was [Ir(H)₂(IMes)(sub)₃]Cl or [IrCl(H)₂(IMes)(sub)₂]. However, when the ionic precatalyst [Ir(COD)(IMes)(pyridine)]BF₄ was used with DMSO-d₆ (2 eq.) a 547-fold signal enhancement for the ¹⁵NO₃⁻ signal at 9.4 T (0.18% ¹⁵N polarisation) is observed.

### Example 18

### Unexpected Reduction of Sodium Nitrate

During the course of these investigations, a ¹⁵N NMR signal appears at δ_{N} 511.28 (J_{HN}=28.5 Hz) appears almost immediately when pyridine is used as a co-ligand. This matches the equatorial NO₂⁻ resonance previously observed for [Ir(H)₂(¹⁵NO₂)(IMes)(pyridine)₂](6_{A}). Relatively strong polarised signals for free and pyridine trans to hydride in [Ir(H)₂(IMes)(py)₃]Cl (δ_{N} 299.6 and 255.7 respectively) were also observed in these NMR spectra. As expected, the corresponding ¹H NMR spectrum is dominated by the hydride signal of [Ir(H)₂(IMes)(py)₃]Cl which appears at δ_{H}−22.7, although a weakly PHIP enhanced signal for 6_{A} is visible in this spectrum at δ_{H}−21.49 (the peak at δ_{H}−22.71 cannot be observed due to overlap). No evidence for 7_{A} was observed in either the ¹H or ¹⁵N NMR spectra which indicates that 6_{A} is likely to be the kinetic product of this reaction. After waiting for 1 h, refreshing the sample with p-H₂ and repeating the SABRE process, a polarised signal for free Na¹⁵NO₂ ((N 611.9) could also be detected and the signal for 6_{A} also increased in size. We therefore suspect that the reducing environment of this medium converts nitrate to nitrite in a metal catalysed reduction. To further probe this reduction, a sample containing [IrCl(COD)(IMes)](20 mM), pyridine (3 eq.) and Na¹⁵NO₃⁻ (25 eq.) was exposed to 3 bar of H₂ at 298 K for 24 h and the growth of the hydride ligand resonance for 6_{A} at δ_{H}-21.49 was monitored by thermally polarised ¹H NMR spectroscopy. The resulting integral data could be fitted to an exponential growth curve. After 24 h, and refreshing the H₂ atmosphere, further conversion to 6_{A} could again be seen which indicates that H₂ is needed to drive this reaction.

### REFERENCES

1. Keshari, K. R.; Wilson, D. M., Chemistry and biochemistry of C-13 hyperpolarized magnetic resonance using dynamic nuclear polarization. Chem. Soc. Rev. 2014, 43 (5), 1627-1659.
2. Mugler, J. P.; Altes, T. A., Hyperpolarized 129Xe MRI of the human lung. J Mag. Res. Imag. 2013, 37 (2), 313-331.
3. Rayner, P. J.; Duckett, S. B., Signal Amplification by Reversible Exchange (SABRE): From Discovery to Diagnosis. Angew. Chem. 2018, 57 (23), 6742-6753.
4. Reineri, F.; Boi, T.; Aime, S., ParaHydrogen Induced Polarization of C-13 carboxylate resonance in acetate and pyruvate. Nat. Comm. 2015, 6, 6.
5. Blazina, D.; Duckett, S. B.; Dunne, J. P.; Godard, C., Applications of the parahydrogen phenomenon in inorganic chemistry. Dalton Trans. 2004, (17), 2601-2609.
6. Shchepin, R. V.; Birchall, J. R.; Chukanov, N. V.; Kovtunov, K. V.; Koptyug, I. V.; Theis, T.; Warren, W. S.; Gelovani, J. G.; Goodson, B. M.; Shokouhi, S.; Rosen, M. S.; Yen, Y. F.; Pham, W.; Chekmenev, E. Y., Hyperpolarising Concentrated Metronidazole (NO2)-N-15 Group over Six Chemical Bonds with More than 15% Polarization and a 20 Minute Lifetime. Chem. E. J 2019, 25 (37), 8829-8836.
7. Shchepin, R. V.; Barskiy, D. A.; Coffey, A. M.; Feldman, M. A.; Kovtunova, L. M.; Bukhtiyarov, V. I.; Kovtunov, K. V.; Goodson, B. M.; Koptyug, I. V.; Chekmenev, E. Y., Robust Imidazole-N-15(2) Synthesis for High-Resolution Low-Field (0.05 T) (15)NHyperpolarized NMR Spectroscopy. Chemistryselect 2017, 2 (16), 4478-4483.
8. Hovener, J. B.; Pravdivtsev, A. N.; Kidd, B.; Bowers, C. R.; Gloggler, S.; Kovtunov, K. V.; Plaumann, M.; Katz-Brull, R.; Buckenmaier, K.; Jerschow, A.; Reineri, F.; Theis, T.; Shchepin, R. V.; Wagner, S.; Bhattacharya, P.; Zacharias, N. M.; Chekmenev, E. Y., Parahydrogen-Based Hyperpolarization for Biomedicine. Angew. Chem. 2018, 57 (35), 11140-11162.
9. Ko, Y.; Bonner, F. T.; Crull, G. B.; Harbison, G. S., Protonation nitrogen shielding and NOE in aqueous nitrite and solid-state nitrogen-15 NMR of nitrosyl and nitryl tetrafluoroborate. Inorg. Chem. 1993, 32 (15), 3316-3319.
10. Thorn, K. A.; Mikita, M. A., Nitrite Fixation by Humic Substances Nitrogen-15 Nuclear Magnetic Resonance Evidence for Potential Intermediates in Chemodenitrification. Soil Science Society of America Journal 2000, 64 (2), 568-582.
11. Sakhaei, Z.; Kundu, S.; Donnelly, J. M.; Bertke, J. A.; Kim, W. Y.; Warren, T. H., Nitric oxide release via oxygen atom transfer from nitrite at copper(ii). Chem. Commun. 2017, 53 (3), 549-552.
12. Gamliel, A.; Uppala, S.; Sapir, G.; Harris, T.; Nardi-Schreiber, A.; Shaul, D.; Sosna, J.; Gomori, J. M.; Katz-Brull, R., Hyperpolarized [15N]nitrate as a potential long lived hyperpolarized contrast agent for MRI. J Magn. Reson. 2019, 299, 188-195.
13. Godard, C.; Lopez-Serrano, J.; Galvez-Lopez, M. D.; Rosello-Merino, M.; Duckett, S. B.; Khazal, I.; Lledos, A.; Whitwood, A. C., Detection of platinum dihydride bisphosphine complexes and studies of their reactivity through para-hydrogen-enhanced NMR methods. Magn. Reson. Chem. 2008, 46, S107-S114.
14. Vazquez-Serrano, L. D.; Owens, B. T.; Buriak, J. M., Catalytic olefin hydrogenation using N-heterocyclic carbene-phosphine complexes of iridium. Chem. Commun. 2002, (21), 2518-2519.
15. Giernoth, R.; Heinrich, H.; Adams, N. J.; Deeth, R. J.; Bargon, J.; Brown, J. M., PHIP detection of a transient rhodium dihydride intermediate in the homogeneous hydrogenation of dehydroamino acids. Journal of the American Chemical Society 2000, 122 (49), 12381-12382.
16. Torres, O.; Procacci, B.; Halse, M. E.; Adams, R. W.; Blazina, D.; Duckett, S. B.; Eguillor, B.; Green, R. A.; Perutz, R. N.; Williamson, D. C., Photochemical Pump and NMR Probe: Chemically Created NMR Coherence on a Microsecond Time Scale. Journal of the American Chemical Society 2014, 136 (28), 10124-10131.
17. Delwiche, C. C., THE NITROGEN CYCLE. Scientific American 1970, 223 (3), 136-147.
18. Cammack, R.; Joannou, C. L.; Cui, X.-Y.; Torres Martinez, C.; Maraj, S. R.; Hughes, M. N., Nitrite and nitrosyl compounds in food preservation. Biochimica et Biophysica Acta (BBA)—Bioenergetics 1999, 1411 (2), 475-488.
19. Shiva, S., Nitrite: A physiological store of nitric oxide and modulator of mitochondrial function. Redox Biology 2013, 1 (1), 40-44.
20. Weitzberg, E., M.D., Ph.D.; Hezel, M., Ph.D.; Lundberg, J. O., M.D., Ph.D., Nitrate-Nitrite-Nitric Oxide Pathway: Implications for Anesthesiology and Intensive Care. Anesthesiology: The Journal of the American Society of Anesthesiologists 2010, 113 (6), 1460-1475.
21. Chui, J. S. W.; Poon, W. T.; Chan, K. C.; Chan, A. Y. W.; Buckley, T. A., Nitrite-induced methaemoglobinaemia—aetiology, diagnosis and treatment. Anaesthesia 2005, 60 (5), 496-500.
22. Additives, E. Panel o. F.; Food, N. S. a. t.; Mortensen, A.; Aguilar, F.; Crebelli, R.; Di Domenico, A.; Dusemund, B.; Frutos, M. J.; Galtier, P.; Gott, D.; Gundert-Remy, U.; Lambré, C.; Leblanc, J.-C.; Lindtner, O.; Moldeus, P.; Mosesso, P.; Oskarsson, A.; Parent-Massin, D.; Stankovic, I.; Waalkens-Berendsen, I.; Woutersen, R. A.; Wright, M.; van den Brandt, P.; Fortes, C.; Merino, L.; Toldri, F.; Arcella, D.; Christodoulidou, A.; Cortinas Abrahantes, J.; Barrucci, F.; Garcia, A.; Pizzo, F.; Battacchi, D.; Younes, M., Re-evaluation of potassium nitrite (E 249) and sodium nitrite (E 250) as food additives. EFSA Journal 2017, 15 (6), e04786.
23. Walker, R., Nitrates, nitrites and N-nitrosocompounds: A review of the occurrence in food and diet and the toxicological implications. Food Additives & Contaminants 1990, 7 (6), 717-768.
24. Bebarta, V. S.; Brittain, M.; Chan, A.; Garrett, N.; Yoon, D.; Burney, T.; Mukai, D.; Babin, M.; Pilz, R. B.; Mahon, S. B.; Brenner, M.; Boss, G. R., Sodium Nitrite and Sodium Thiosulfate Are Effective Against Acute Cyanide Poisoning When Administered by Intramuscular Injection. Ann Emerg Med 2017, 69 (6), 718-725.e4.
25. Mukhopadhyay, S.; Batra, S., Applications of Sodium Nitrite in Organic Synthesis. Eur. J. Org. Chem. 2019, 2019 (38), 6424-6451.
26. Halfen, J. A.; Mahapatra, S.; Wilkinson, E. C.; Gengenbach, A. J.; Young, V. G.; Que, L.; Tolman, W. B., Synthetic Modeling of Nitrite Binding and 50 Activation by Reduced Copper Proteins. Characterization of Copper(I)-Nitrite Complexes That Evolve Nitric Oxide. Journal of the American Chemical Society 1996, 118 (4), 763-776.
27. Timmons, A. J.; Symes, M. D., Converting between the oxides of nitrogen using metal-ligand coordination complexes. Chem. Soc. Rev. 2015, 44 (19), 6708-6722.
28. Takeuchi, A.; Sato, K.; Sone, K.; Yamada, S.; Yamasaki, K., Preparation of some nitro-amine complexes of nickel and their properties. Inorg. Chim. Acta 1967, 1, 399-402.
29. Goodgame, D. M. L.; Hitchman, M. A., Studies of Nitro and Nitrito Complexes. I. Some Nitrito Complexes of Nickel(II). Inorg. Chem. 1964, 3 (10), 1389-1394.
30. Goodgame, D. M. L.; Hitchman, M. A., Studies of Nitro and Nitrito Complexes. III. Some Nitro Complexes of Nickel(II) and a Nitro-Nitrito Equilibrium. Inorg. Chem. 1966, 5 (8), 1303-1307.
31. Gwak, J.; Ahn, S.; Baik, M.-H.; Lee, Y., One metal is enough: a nickel complex reduces nitrate anions to nitrogen gas. Chem. Sci. 2019, 10 (18), 4767-4774.
32. Nakamura, I.; Funasako, Y.; Mochida, T., Nitro-Nitrito Photoisomerization of Platinum(II) Complexes with Pt(NO2)42- and (FSO2)2N— Anions: Correlation between Isomerization Ratio and Reaction Cavity. Crystal Growth & Design 2020, 20 (12), 8047-8052.
33. Badar Ud, D.; Bailar, J. C., Observations on the oxidation and reduction of platinum(II) nitro complexes. J. Inorg. Nucl. Chem. 1961, 22 (3), 241-245.
34. Gel'fman, M. I.; Starkina, N. A.; Salishcheva, O. V.; Moldagulova, N. E., Trans-influence of a nitro group in platinum complexes. Russian Journal of Inorganic Chemistry 2007, 52 (10), 1551-1556.
35. Adams, R. W.; Aguilar, J. A.; Atkinson, K. D.; Cowley, M. J.; Elliott, P. I.; Duckett, S. B.; Green, G. G.; Khazal, I. G.; López-Serrano, J.; Williamson, D. C., Reversible interactions with para-hydrogen enhance NMR sensitivity by polarization transfer. Science 2009, 323 (5922), 1708-1711.
36. Rayner, P. J.; Duckett, S., Signal Amplification by Reversible Exchange (SABRE): From Discovery to Diagnosis. Angew. Chem. Int. Ed. 2018, 57 (23), 6742-6753.
37. Kovtunov, K. V.; Pokochueva, E. V.; Salnikov, 0. G.; Cousin, S. F.; Kurzbach, D.; Vuichoud, B.; Jannin, S.; Chekmenev, E. Y.; Goodson, B. M.; Barskiy, D. A.; Koptyug, I. V., Hyperpolarized NMR Spectroscopy: d-DNP, PHIP, and SABRE Techniques. Chem. Asian J. 2018, 13 (15), 1857-1871.
38. Hövener, J.-B.; Pravdivtsev, A. N.; Kidd, B.; Bowers, C. R.; Gloggler, S.; Kovtunov, K. V.; Plaumann, M.; Katz-Brull, R.; Buckenmaier, K.; Jerschow, A.; Reineri, F.; Theis, T.; Shchepin, R. V.; Wagner, S.; Bhattacharya, P.; Zacharias, N. M.; Chekmenev, E. Y., Parahydrogen-Based Hyperpolarization for Biomedicine. Angew. Chem. Int. Ed 2018, 57, 11140-11162.
39. Tickner, B. J.; Semenova, O.; Iali, W.; Rayner, P. J.; Whitwood, A. C.; Duckett, S. B., Optimisation of pyruvate hyperpolarisation using SABRE by tuning the active magnetisation transfer catalyst. Catal. Sci. Technol. 2020, 10 (5), 1343-1355.
40. Iali, W.; Roy, S. S.; Tickner, B. J.; Ahwal, F.; Kennerley, A. J.; Duckett, S. B., Hyperpolarising Pyruvate through Signal Amplification by Reversible Exchange (SABRE). Angew. Chem. 2019, 131 (30), 10377-10381.
41. Gemeinhardt, M.; Limbach, M.; Gebhardt, T.; Eriksson, C.; Eriksson, S.; Lindale, J.; Goodson, E.; Warren, W.; Chekmenev, E.; Goodson, B., “Direct” 13C Hyperpolarization of 13C-Acetate by MicroTesla NMR Signal Amplification by Reversible Exchange (SABRE). Angew. Chem. Int. Ed. 2020, 59, 418-423.
42. Rayner, P. J.; Burns, M. J.; Olaru, A. M.; Norcott, P.; Fekete, M.; Green, G. G. R.; Highton, L. A. R.; Mewis, R. E.; Duckett, S. B., Delivering strong 1H nuclear hyperpolarization levels and long magnetic lifetimes through signal amplification by reversible exchange. Proc. Natl. Acad. Sci. U.S.A. 2017, 114 (16), E3188-E3194.
43. Adams, R. W.; Duckett, S. B.; Green, R. A.; Williamson, D. C.; Green, G. G. R., A theoretical basis for spontaneous polarization transfer in non-hydrogenative parahydrogen-induced polarization. J Chem. Phys. 2009, 131 (19), 194505.
44. Barskiy, D. A.; Pravdivtsev, A. N.; Ivanov, K. L.; Kovtunov, K. V.; Koptyug, I. V., A simple analytical model for signal amplification by reversible exchange (SABRE) process. Phys. Chem. Chem. Phys 2016, 18 (1), 89-93.
45. Knecht, S.; Pravdivtsev, A. N.; Hovener, J.-B.; Yurkovskaya, A. V.; Ivanov, K. L., Quantitative description of the SABRE process: rigorous consideration of spin dynamics and chemical exchange. RSC Adv. 2016, 6 (29), 24470-24477.
46. Pravdivtsev, A. N.; Yurkovskaya, A. V.; Vieth, H.-M.; Ivanov, K. L.; Kaptein, R., Level Anti-Crossings are a Key Factor for Understanding para-Hydrogen-Induced Hyperpolarization in SABRE Experiments. ChemPhysChem 2013, 14 (14), 3327-3331.
47. Barskiy, D. A.; Pravdivtsev, A. N.; Ivanov, K. L.; Kovtunov, K. V.; Koptyug, I. V., A simple analytical model for signal amplification by reversible exchange (SABRE) process. Phy. Chem. Chem. Phy. 2016, 18 (1), 89-93.
48. Adams, R. W.; Duckett, S. B.; Green, R. A.; Williamson, D. C.; Green, G. G. R., A theoretical basis for spontaneous polarization transfer in non-hydrogenative parahydrogen-induced polarization. J. Chem. Phys. 2009, 131 (19), 15.
49. Pravdivtsev, A. N.; Ivanov, K. L.; Yurkovskaya, A. V.; Petrov, P. A.; Limbach, H. H.; Kaptein, R.; Vieth, H. M., Spin polarization transfer mechanisms of SABRE: A magnetic field dependent study. J. Magn. Reson. 2015, 261, 73-82.
50. Knecht, S.; Pravdivtsev, A. N.; Hovener, J. B.; Yurkovskaya, A. V.; Ivanov, K. L., Quantitative description of the SABRE process: rigorous consideration of spin dynamics and chemical exchange. Rsc Advances 2016, 6 (29), 24470-24477.
51. Theis, T.; Truong, M.; Coffey, A. M.; Chekmenev, E. Y.; Warren, W. S., LIGHT-SABRE enables efficient in-magnet catalytic hyperpolarization. J Magn. Reson. 2014, 248, 23-26.
52. Barskiy, D. A.; Shchepin, R. V.; Tanner, C. P. N.; Colell, J. F. P.; Goodson, B. M.; Theis, T.; Warren, W. S.; Chekmenev, E. Y., The Absence of Quadrupolar Nuclei Facilitates Efficient 13C Hyperpolarization via Reversible Exchange with Parahydrogen. ChemPhysChem 2017, 18 (12), 1493-1498.
53. Zhou, Z.; Yu, J.; Colell, J. F. P.; Laasner, R.; Logan, A.; Barskiy, D. A.; Shchepin, R. V.; Chekmenev, E. Y.; Blum, V.; Warren, W. S.; Theis, T., 50 Long-Lived 13C2 Nuclear Spin States Hyperpolarized by Parahydrogen in Reversible Exchange at Microtesla Fields. J. Phys. Chem. Lett. 2017, 8 (13), 3008-3014.
54. Theis, T.; Truong, M. L.; Coffey, A. M.; Shchepin, R. V.; Waddell, K. W.; Shi, F.; Goodson, B. M.; Warren, W. S.; Chekmenev, E. Y., Microtesla SABRE Enables 10% Nitrogen-15 Nuclear Spin Polarization. Journal of the American Chemical Society 2015, 137 (4), 1404-1407.
55. Roy, S. S.; Rayner, P. J.; Burns, M. J.; Duckett, S. B., A simple and cost-efficient technique to generate hyperpolarized long-lived 15N-15N nuclear spin order in a diazine by signal amplification by reversible exchange. J. Chem. Phys. 2020, 152 (1), 014201.
56. Shchepin, R. V.; Barskiy, D. A.; Mikhaylov, D. M.; Chekmenev, E. Y., Efficient Synthesis of Nicotinamide-1-15N for Ultrafast NMR Hyperpolarization Using Parahydrogen. Bioconjugate Chem. 2016, 27 (4), 878-882.
57. Theis, T.; Ortiz, G. X.; Logan, A. W. J.; Claytor, K. E.; Feng, Y.; Huhn, W. P.; Blum, V.; Malcolmson, S. J.; Chekmenev, E. Y.; Wang, Q.; Warren, W. S., Direct and cost-efficient hyperpolarization of long-lived nuclear spin states on universal <sup>15</sup>N<sub>2</sub>-diazirine molecular tags. Sci. Adv. 2016, 2 (3), e1501438.
58. Barskiy, D. A.; Shchepin, R. V.; Coffey, A. M.; Theis, T.; Warren, W. S.; Goodson, B. M.; Chekmenev, E. Y., Over 20% 15N Hyperpolarization in Under One Minute for Metronidazole, an Antibiotic and Hypoxia Probe. Journal of the American Chemical Society 2016, 138 (26), 8080-8083.
59. Truong, M. L.; Theis, T.; Coffey, A. M.; Shchepin, R. V.; Waddell, K. W.; Shi, F.; Goodson, B. M.; Warren, W. S.; Chekmenev, E. Y., 15N Hyperpolarization by Reversible Exchange Using SABRE-SHEATH. J. Phys. Chem. C 2015, 119 (16), 8786-8797.
60. Zhivonitko, V. V.; Skovpin, I. V.; Koptyug, I. V., Strong ³¹P nuclear spin hyperpolarization produced via reversible chemical interaction with parahydrogen. Chem. Commun. 2015, 51, 2506-2509.
61. Burns, M. J.; Rayner, P. J.; Green, G. G. R.; Highton, L. A. R.; Mewis, R. E.; Duckett, S. B., Improving the Hyperpolarization of 31P Nuclei by Synthetic Design. J. Phys. Chem. B 2015, 119 (15), 5020-5027.
62. Olaru, A. M.; Burt, A.; Rayner, P. J.; Hart, S. J.; Whitwood, A. C.; Green, G. G. R.; Duckett, S. B., Using signal amplification by reversible exchange (SABRE) to hyperpolarise 119Sn and 29Si NMR nuclei. Chem. Commun. 2016, 52 (100), 14482-14485.
63. Rayner, P. J.; Norcott, P.; Appleby, K. M.; Iali, W.; John, R. O.; Hart, S. J.; Whitwood, A. C.; Duckett, S. B., Fine-tuning the efficiency of para-hydrogen-induced hyperpolarization by rational N-heterocyclic carbene design. Nat. Commun. 2018, 9 (1), 4251.
64. Cowley, M. J.; Adams, R. W.; Atkinson, K. D.; Cockett, M. C. R.; Duckett, S. B.; Green, G. G. R.; Lohman, J. A. B.; Kerssebaum, R.; Kilgour, D.; Mewis, R. E., Iridium N-Heterocyclic Carbene Complexes as Efficient Catalysts for Magnetization Transfer from para-Hydrogen. J. Am. Chem. Soc. 2011, 133 (16), 6134-6137.
65. Rayner, P. J.; Norcott, P.; Appleby, K. M.; Iali, W.; John, R. O.; Hart, S. J.; Whitwood, A. C.; Duckett, S. B., Fine-tuning the efficiency of para-hydrogen-induced hyperpolarization by rational N-heterocyclic carbene design. Nat. Comm. 2018, 9, 11.
66. Barskiy, D. A.; Shchepin, R. V.; Coffey, A. M.; Theis, T.; Warren, W. S.; Goodson, B. M.; Chekmenev, E. Y., Over 20% N-15 Hyperpolarization in Under One Minute for Metronidazole, an Antibiotic and Hypoxia Probe. J Am. Chem. Soc. 2016, 138 (26), 8080-8083.
67. Truong, M. L.; Theis, T.; Coffey, A. M.; Shchepin, R. V.; Waddell, K. W.; Shi, F.; Goodson, B. M.; Warren, W. S.; Chekmenev, E. Y., N-15 Hyperpolarization by Reversible Exchange Using SABRE-SHEATH. J. Phys. Chem. C 2015, 119 (16), 8786-8797.
68. Fekete, M.; Ahwal, F.; Duckett, S. B., Remarkable Levels of N-15 Polarization Delivered through SABRE into Unlabeled Pyridine, Pyrazine, or Metronidazole Enable Single Scan NMR Quantification at the mM Level. Journal of Physical Chemistry B 2020, 124 (22), 4573-4580.
69. Eshuis, N.; van Weerdenburg, B. J. A.; Feiters, M. C.; Rutjes, F. P. J. T.; Wijmenga, S. S.; Tessari, M., Quantitative Trace Analysis of Complex Mixtures Using SABRE Hyperpolarization. Angew. Chem. 2015, 54 (5), 1481-1484.
70. van Weerdenburg, B. J. A.; Gloeggler, S.; Eshuis, N.; Engwerda, A. H. J.; Smits, J. M. M.; de Gelder, R.; Appelt, S.; Wymenga, S. S.; Tessari, M.; Feiters, M. C.; Blumich, B.; Rutjes, F. P. J. T., Ligand effects of NHC-iridium catalysts for signal amplification by reversible exchange (SABRE). Chem. Com. 2013, 49 (67), 7388-7390.
71. Roy, S. S.; Norcott, P.; Rayner, P. J.; Green, G. G. R.; Duckett, S. B., A Hyperpolarizable 1H Magnetic Resonance Probe for Signal Detection 15 Minutes after Spin Polarization Storage. Angew. Chem. 2016, 55 (50), 15642-15645.
72. Levitt, M. H., Singlet NMR. In A. Rev. Phys. Chem., 2012; pp 89-105.
73. Shen, K.; Logan, A. W. J.; Colell, J. F. P.; Bae, J.; Ortiz Jr., G. X.; Theis, T.; Warren, W. S.; Malcolmson, S. J.; Wang, Q., Diazirines as Potential Molecular Imaging Tags: Probing the Requirements for Efficient and Long-Lived SABRE-Induced Hyperpolarization. Angew. Chem. 2017, 129 (40), 12280-12284.
74. Norcott, P.; Burns, M. J.; Rayner, P. J.; Mewis, R. E.; Duckett, S. B., Using 2H Labelling to Improve the NMR Detectability of Pyridine and its Derivatives by SABRE. Magn. Reson. Chem. 2018, 10.1002/mrc.4703.
75. Norcott, P.; Rayner, P. J.; Green, G. G. R.; Duckett, S., Achieving High 1H Nuclear Hyperpolarization Levels with Long Lifetimes in a Range of Tuberculosis Drug Scaffolds. Chem.—Eur. J. 2017, 23, 16990-16997.
76. Fekete, M.; Bayfield, O.; Duckett, S. B.; Hart, S.; Mewis, R. E.; Pridmore, N.; Rayner, P. J.; Whitwood, A., Iridium(III) Hydrido N-Heterocyclic Carbene-Phosphine Complexes as Catalysts in Magnetization Transfer Reactions. Inorg. Chem. 2013, 52 (23), 13453-13461.
77. Lloyd, L. S.; Asghar, A.; Burns, M. J.; Charlton, A.; Coombes, S.; Cowley, M. J.; Dear, G. J.; Duckett, S. B.; Genov, G. R.; Green, G. G. R.; Highton, L. A. R.; Hooper, A. J. J.; Khan, M.; Khazal, I. G.; Lewis, R. J.; Mewis, R. E.; Roberts, A. D.; Ruddlesden, A. J., Hyperpolarisation through reversible interactions with parahydrogen. Catal. Sci. Technol. 2014, 4 (10), 3544-3554.
78. Iali, W.; Roy, S. S.; Tickner, B. J.; Ahwal, F.; Kennerley, A. J.; Duckett, S. B., Hyperpolarising Pyruvate through Signal Amplification by Reversible Exchange (SABRE). 2019, 58 (30), 10271-10275.
79. Rayner, P. J.; Gillions, J. P.; Hannibal, V. D.; John, R. O.; Duckett, S. B., Hyperpolarisation of weakly binding N-heterocycles using signal amplification by reversible exchange. Chem. Sci. 2021.
80. Zhang, G. N.; Colell, J. F. P.; Glachet, T.; Lindale, J. R.; Reboul, V.; Theis, T.; Warren, W. S., Terminal Diazirines Enable Reverse Polarization Transfer from N-15(2) Singlets. Angew. Chem. 2019, 58 (32), 11118-11124.
81. Rayner, P. J.; Tickner, B. J.; Iali, W.; Fekete, M.; Robinson, A. D.; Duckett, S. B., Relayed hyperpolarization from para-hydrogen improves the NMR detectability of alcohols. Chem. Sci. 2019, 10 (33), 7709-7717.
82. Iali, W.; Rayner, P. J.; Duckett, S. B., Using parahydrogen to hyperpolarize amines, amides, carboxylic acids, alcohols, phosphates, and carbonates. Sci. Adv. 2018, 4 (1), eaao6250.
83. Shchepin, R. V.; Truong, M. L.; Theis, T.; Coffey, A. M.; Shi, F.; Waddell, K. W.; Warren, W. S.; Goodson, B. M.; Chekmenev, E. Y., Hyperpolarization of “Neat” Liquids by NMR Signal Amplification by Reversible Exchange. J. Phys. Chem. Lett. 2015, 6 (10), 1961-1967.
84. Colell, J.; Logan, A. W. J.; Zhou, Z.; Lindale, J. R.; Laasner, R.; Shchepin, R.; Chekmenev, E.; Blum, V.; Warren, W. S.; Malcolmson, S. J.; Theis, T., Rational ligand choice extends the SABRE substrate scope. Chem. Commun. 2020, 56, 9336-9339.
85. Iali, W.; Rayner, P. J.; Alshehri, A.; Holmes, A. J.; Ruddlesden, A. J.; Duckett, S. B., Direct and indirect hyperpolarisation of amines using parahydrogen. Chem. Sci. 2018, 9, 3677-3684.
86. Rayner, P. J.; Richardson, P. M.; Duckett, S. B., The Detection and Reactivity of Silanols and Silanes Using Hyperpolarized 29Si Nuclear Magnetic Resonance. Angew. Chem. Int. Ed. 2020, 59 (7), 2710-2714.
87. Richardson, P. M.; Iali, W.; Roy, S. S.; Rayner, P. J.; Halse, M. E.; Duckett, S. B., Rapid 13C NMR hyperpolarization delivered from para-hydrogen enables the low concentration detection and quantification of sugars. Chem. Sci. 2019, 10, 10607-10619.
88. Tickner, B. J.; Lewis, J. S.; John, R. O.; Whitwood, A. C.; Duckett, S. B., Mechanistic insight into novel sulfoxide containing SABRE polarisation transfer catalysts. Dalton Trans. 2019, 48 (40), 15198-15206.
89. Mewis, R. E.; Green, R. A.; Cockett, M. C. R.; Cowley, M. J.; Duckett, S. B.; Green, G. G. R.; John, R. O.; Rayner, P. J.; Williamson, D. C., Strategies for the Hyperpolarization of Acetonitrile and Related Ligands by SABRE. J. Phys. Chem. B 2015, 119 (4), 1416-1424.
90. Roy, S. S.; Norcott, P.; Rayner, P. J.; Green, G. G. R.; Duckett, S. B., A Hyperpolarizable 1H Magnetic Resonance Probe for Signal Detection 15 Minutes after Spin Polarization Storage. Angew. Chem. 2016, 128 (50), 15871-15874.
91. Bagley, M. C.; Alnomsy, A.; Sharhan, H. I., Rapid Protium-Deuterium Exchange of 4-Aminopyridines in Neutral D2O under Microwave Irradiation. Synlett 2016, 27 (17), 2467-2472.
92. van Weerdenburg, B. J. A.; Eshuis, N.; Tessari, M.; Rutjes, F. P. J. T.; Feiters, M. C., Application of the [small pi]-accepting ability parameter of N-heterocyclic carbene ligands in iridium complexes for signal amplification by reversible exchange (SABRE). Dalton Trans. 2015, 44 (35), 15387-15390.
93. Poater, A.; Cosenza, B.; Correa, A.; Giudice, S.; Ragone, F.; Scarano, V.; Cavallo, L., SambVca: A Web Application for the Calculation of the Buried Volume of N-Heterocyclic Carbene Ligands. Eur. J Inorg. Chem. 2009, 2009 (13), 1759-1766.
94. Zhang, Y.; Lavigne, G.; Lugan, N.; Cesar, V., Buttressing Effect as a Key Design Principle towards Highly Efficient Palladium/N-Heterocyclic Carbene Buchwald-Hartwig Amination Catalysts. Chem.—Eur. J. 2017, 23 (55), 13792-13801.
95. Zhang, Y.; Cesar, V.; Storch, G.; Lugan, N.; Lavigne, G., Skeleton Decoration of NHCs by Amino Groups and its Sequential Booster Effect on the Palladium-Catalyzed Buchwald-Hartwig Amination. Angew. Chem. Int. Ed 2014, 53 (25), 6482-6486.
96. Izatt, R. M.; Bradshaw, J. S.; Nielsen, S. A.; Lamb, J. D.; Christensen, J. J.; Sen, D., Thermodynamic and kinetic data for cation-macrocycle interaction. Chem. Rev. 1985, 85 (4), 271-339.
97. More, M. B.; Ray, D.; Armentrout, P. B., Intrinsic Affinities of Alkali Cations for 15-Crown-5 and 18-Crown-6: Bond Dissociation Energies of Gas-Phase M+-Crown Ether Complexes. Journal of the American Chemical Society 1999, 121 (2), 417-423.
98. Iali, W.; Olaru, A. M.; Green, G. G. R.; Duckett, S. B., Achieving High Levels of NMR-Hyperpolarization in Aqueous Media With Minimal Catalyst Contamination Using SABRE. Chem.—Eur. J. 2017, 23, 10491-10495.
99. Kidd, B. E.; Gesiorski, J. L.; Gemeinhardt, M. E.; Shchepin, R. V.; Kovtunov, K. V.; Koptyug, I. V.; Chekmenev, E. Y.; Goodson, B. M., Facile Removal of Homogeneous SABRE Catalysts for Purifying Hyperpolarized Metronidazole, a Potential Hypoxia Sensor. J. Phys. Chem. C 2018, 122 (29), 16848-16852.
100. Manoharan, A.; Rayner, P. J.; Iali, W.; Burns, M. J.; Perry, V. H.; Duckett, S. B., Achieving Biocompatible SABRE: An in vitro Cytotoxicity Study. ChemMedChem 2018, 13 (4), 352-359.
101. Landini, D.; Maia, A.; Montanari, F.; Pirisi, F. M., Crown ethers as phase-transfer catalysts. A comparison of anionic activation in aqueous-organic two-phase systems and in low polarity anhydrous solutions by perhydrodibenzo-18-crown-6, lipophilic quaternary salts, and cryptands. Journal of the Chemical Society, Perkin Transactions 2 1980, (1), 46-51.
102. Hodgson, H. H., The Sandmeyer Reaction. Chem. Rev. 1947, 40 (2), 251-277.
103. Sandmeyer, T., Ueber die Ersetzung der Amidgruppe durch Chlor in den aromatischen Substanzen. Berichte der deutschen chemischen Gesellschaft 1884, 17 (2), 1633-1635.
104. Mo, F.; Qiu, D.; Zhang, Y.; Wang, J., Renaissance of Sandmeyer-Type Reactions: Conversion of Aromatic C—N Bonds into C—X Bonds (X═B, Sn, P, or CF3). Acc. Chem. Res. 2018, 51 (2), 496-506.
105. Leas, D. A.; Dong, Y.; Vennerstrom, J. L.; Stack, D. E., One-Pot, Metal-Free Conversion of Anilines to Aryl Bromides and Iodides. Org. Lett. 2017, 19 (10), 2518-2521.
106. Liu, Q.; Sun, B.; Liu, Z.; Kao, Y.; Dong, B.-W.; Jiang, S.-D.; Li, F.; Liu, G.; Yang, Y.; Mo, F., A general electrochemical strategy for the Sandmeyer reaction. Chem. Sci. 2018, 9 (46), 8731-8737.
107. Zhong, T.; Pang, M.-K.; Chen, Z.-D.; Zhang, B.; Weng, J.; Lu, G., Copper-free Sandmeyer-type Reaction for the Synthesis of Sulfonyl Fluorides. Org. Lett. 2020, 22 (8), 3072-3078.
108. Olah, G. A.; Herges, R.; Laali, K.; Segal, G. A., Onium ions. 34. The methoxydiazonium ion: preparation, proton, carbon-13, and nitrogen-15 NMR and IR structural studies, theoretical calculations, and reaction with aromatics. Attempted preparation and the intermediacy of the hydroxydiazonium ion. Journal of the American Chemical Society 1986, 108 (8), 2054-2057.
109. Elofson, R. M.; Cyr, N.; Laidler, J. K.; Schulz, K. F.; Gadallah, F. F., Correlation of 13C and 15N nuclear magnetic resonance chemical shifts with polarographic reduction potentials of para-substituted benzenediazonium salts and their electronic structures. Can. J. Chem. 1984, 62 (1), 92-95.
110. Barraclough, R.; Jones, F.; Patterson, D.; Tetlow, A., The Photochemical Decomposition of Aryldiazonium Salts I-Stability and Quantum Yields. Journal of the Society of Dyers and Colourists 1972, 88 (1), 22-25.
111. Mo, F.; Dong, G.; Zhang, Y.; Wang, J., Recent applications of arene diazonium salts in organic synthesis. Organic & Biomolecular Chemistry 2013, 11 (10), 1582-1593.
112. Ritchie, C. D.; Wright, D. J., Anion-cation combination reactions. III. Reaction of diazonium ions with azide ion in aqueous solution. Journal of the American Chemical Society 1971, 93 (10), 2429-2432.
113. N. Butler, R.; Fox, A.; Collier, S.; A. Burke, L., Pentazole chemistry: the mechanism of the reaction of aryldiazonium chlorides with azide ion at −80° C.: concerted versus stepwise formation of arylpentazoles, detection of a pentazene intermediate, a combined 1H and 15N NMR experimental and ab initio theoretical study. Journal of the Chemical Society, Perkin Transactions 2 1998, (10), 2243-2248.
114. Joshi, S. M.; de Cózar, A.; Gómez-Vallejo, V.; Koziorowski, J.; Llop, J.; Cossio, F. P., Synthesis of radiolabelled aryl azides from diazonium salts: experimental and computational results permit the identification of the preferred mechanism. Chem. Commun. 2015, 51 (43), 8954-8957.
115. Procacci, B.; Roy, S. S.; Norcott, P.; Turner, N.; Duckett, S. B., Unlocking a Diazirine Long-Lived Nuclear Singlet State via Photochemistry: NMR Detection and Lifetime of an Unstabilized Diazo-Compound. Journal of the American Chemical Society 2018, 140 (48), 16855-16864.
116. Vaneeckhaute, E.; De Ridder, S.; Tyburn, J.-M.; Kempf, J. G.; Taulelle, F.; Martens, J. A.; Breynaert, E., Long-Term Generation of Longitudinal Spin Order Controlled by Ammonia Ligation Enables Rapid SABRE Hyperpolarized 2D NMR. ChemPhysChem 2021, 22 (12), 1170-1177.
117. Krushna, C.; Mohapatra, C.; Dash, K. C., 4-, 5- and 6-coordinate complexes of copper(II) with substituted imidazoles. J. Inorg. Nucl. Chem. 1977, 39 (7), 1253-1258.
118. Mu, J.; Perlmutter, D. D., Thermal decomposition of metal nitrates and their hydrates. Thermochim. Acta 1982, 56 (3), 253-260.
119. Dollimore, D.; Gamlen, G. A.; Taylor, T. J., Degradation studies on nickel nitrate hexahydrate: Part 2. evolved gas analysis. Thermochim. Acta 1985, 91, 287-297.
120. Dollimore, D.; Gamlen, G. A.; Taylor, T. J., Degradation studies on nickel nitrate hexahydrate. Part 1. Effect of experimental conditions. Thermochim. Acta 1985, 86, 119-132.
121. Wheeler, M. T.; Walmsley, F., Transition metal nitrate complexes of 1,4,5-triazanaphthalene. Thermochim. Acta 1986, 108, 325-336.

1. A method for the magnetic resonance studies of a sample using an MRI active ¹⁵N form in solution or liquid comprising:
hyperpolarising a ¹⁵N-form using SABRE;
delivering the hyperpolarised ¹⁵N to a predetermined region of a sample;
applying a magnetic field to the sample;
exciting the predetermined region of the sample with an excitation pulse suitable for exciting an NMR signal from ¹⁵N in the applied magnetic field; and
acquiring magnetic resonance data associated with ¹⁵N from the sample;
wherein the step of hyperpolarisation includes the use of a SABRE hyperpolarisation catalyst.

2. A method according to claim 1 wherein PHIP is used to hyperpolarise the MRI active ¹⁵N forms.

3. A method according to claim 2 wherein the use of PHIP creates an imbalance in one of the two possible nuclear spin orientations (+½ or −½) of ¹⁵N.

4. A method according to claim 1 wherein the ¹⁵N species comprises one or more of nitrite (NO₂⁻), ammonia (NH₃), ammonium (NH₄⁺), hydroxylamine (NH₂OH), hydrazine (N²H₄), nitrosonium (NO⁺), dinitrogen (N₂), nitrate (NO₃⁻), azide (N₃⁻), isocyanate (NCO⁻/RNCO), cyanate (OCN⁻/ROCN), thiocyanate (SCN⁻), amine (RNH₂, etc.) and nitrous oxide (N₂O).

5. (canceled)

6. (canceled)

7. (canceled)

8. A method according to claim 1 wherein a target molecule is a polarisable molecule, such as, but without limitation thereto, pyruvate, glycine, nicotinamide, etc.

9. A method according to claim 1 wherein the target molecule is a polarisable molecule, containing at least one —NH and may optionally comprise an amine or amide moiety.

10. A method according to claim 1 wherein the target molecule is a polarisable molecule, containing at least one —NH comprises, individually or in combination, a primary, secondary or tertiary amine, such as NH₃, NH₂OH, N²H₄, NH₂Ph, NH₂CH₂Ph, NH₂CH₂HCH₂CH₂Ph and related amines; or an amide, such as NH₂COCH₃ or NH₂CONH₂; and the like.

11. (canceled)

12. A method according to claim 1 wherein a source of ¹⁵N contains ²H-counterparts of protons or mixtures thereof and wherein the ²H— includes ammonia (ND3, ND²H and NDH₂), ammonium (ND₄^{±}, ND₃H⁺, ND²H₂^{±} and ND₃H⁺), hydroxylamine (NH₂OD, NHDOD, NHDOH, ND₂OD and ND₂OH), amine (RNHD, RND₂, R′RND where R/R′ is a suitable group like alkyl or aryl), hydrazine (N₂D₄, N₂D₃H, N₂D₂H₂ and N₂DH₃) etc.

13. (canceled)

14. (canceled)

15. A method according to claim 1 wherein the step of hyperpolarisation includes the use of a SABRE hyperpolarisation catalyst and wherein the SABRE hyperpolarisation catalyst comprises a transition metal complex, comprising a metal atom selected from, Ru, Rh, Ir, W, Pd and Pt.

16. (canceled)

17. A method according to claim 15 wherein the SABRE hyperpolarisation catalyst comprises an iridium based catalyst.

18. A method according to claim 15 wherein the SABRE hyperpolarisation catalysts is described in International patent application No. PCT/GB2009/002860.

19. A method according to claim 15 wherein the SABRE hyperpolarisation catalyst is a homogeneous catalyst selected from the group consisting of rhodium based catalysts, such as Wilkinson's catalyst and iridium based catalysts, such as Crabtree's catalyst.

20. A method according to claim 15 wherein the SABRE hyperpolarisation catalyst is a heterogeneous catalyst selected from the group consisting of one or more platinum group metals, particularly platinum, palladium, rhodium and ruthenium, precious metal catalysts, such as silver or gold, or non-precious metal catalysts, such as those based on nickel, e.g. Raney nickel.

21. A method according to claim 15 wherein an iridium N-heterocyclic carbene (NHC) catalyst is used.

22. A method according to claim 1 wherein the SABRE hyperpolarisation catalyst is selected from the group consisting of N-heterocyclic carbenes:

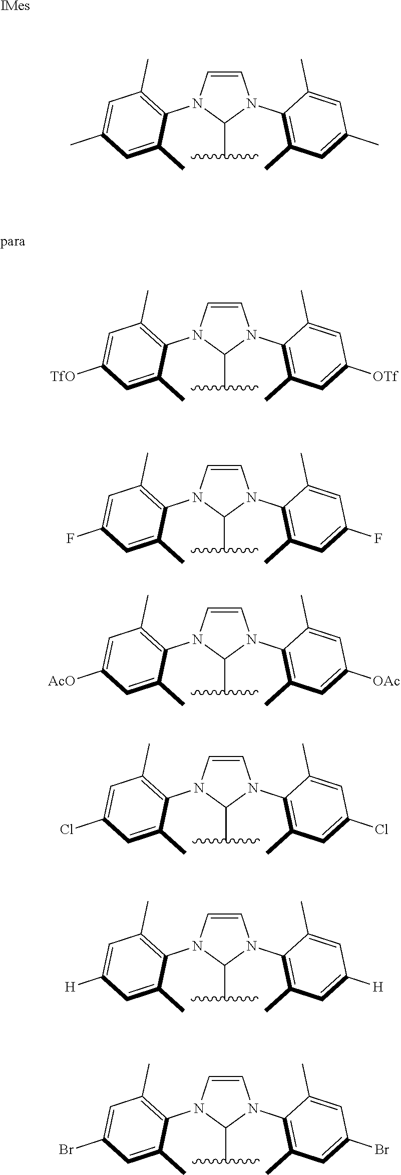

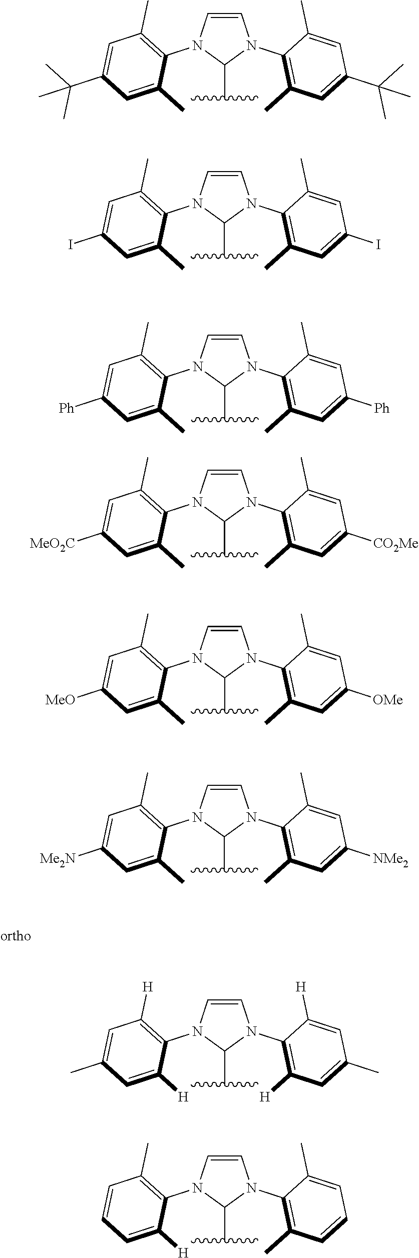

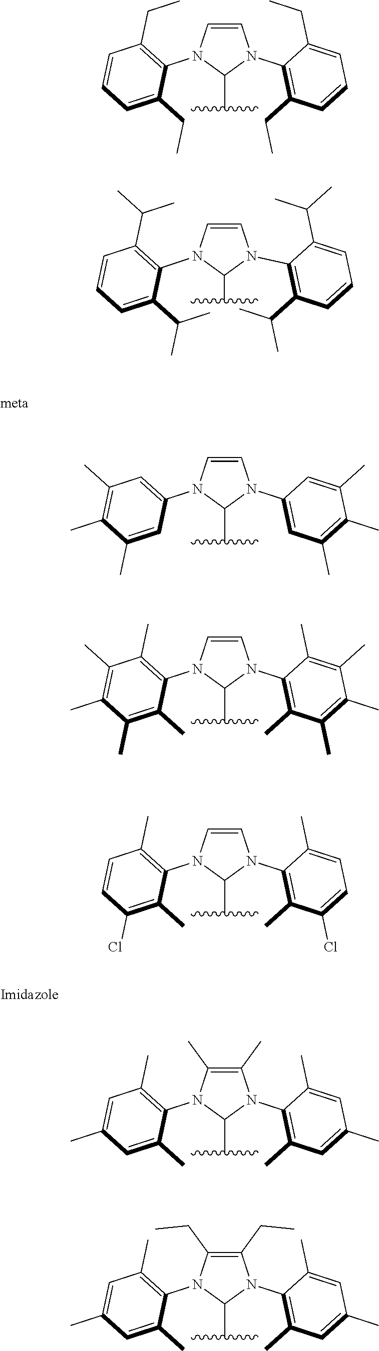

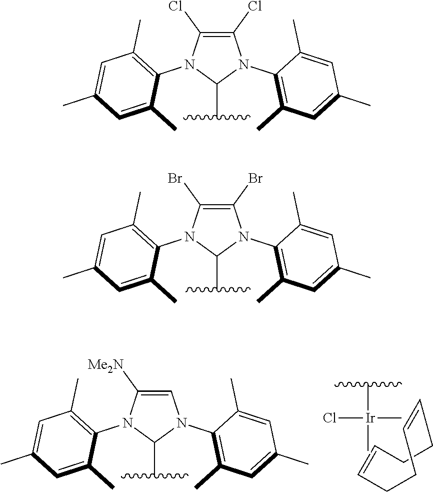

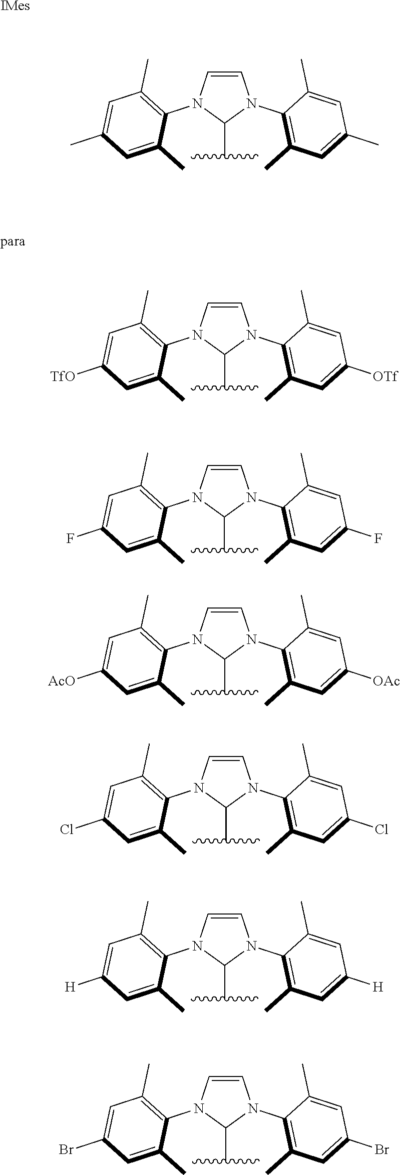

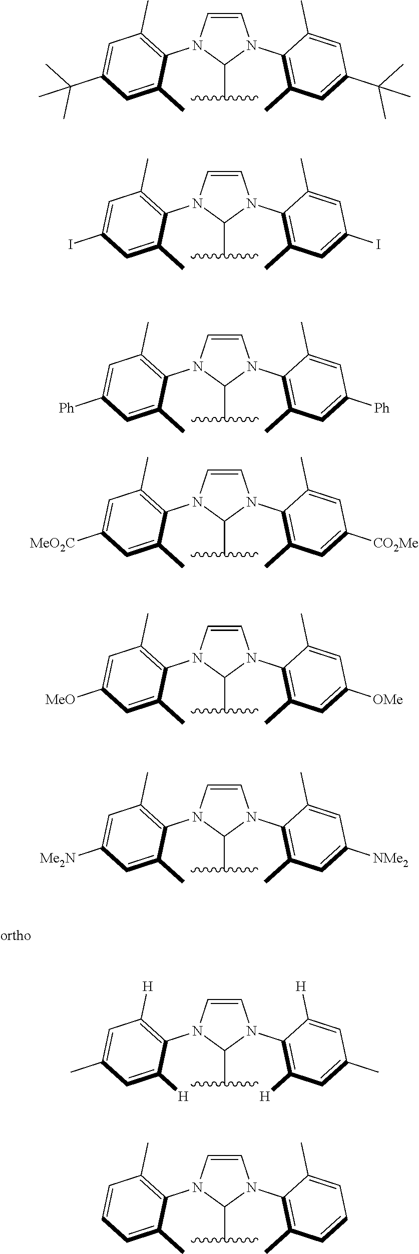

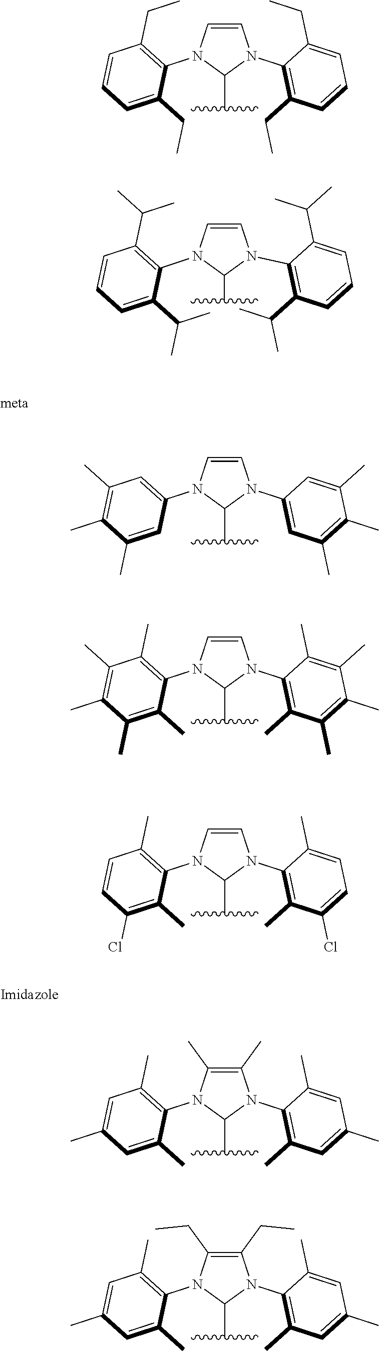

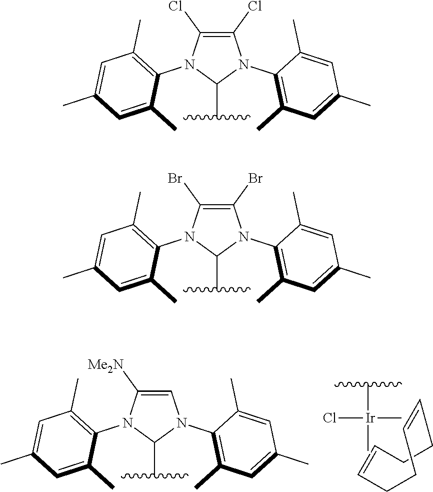

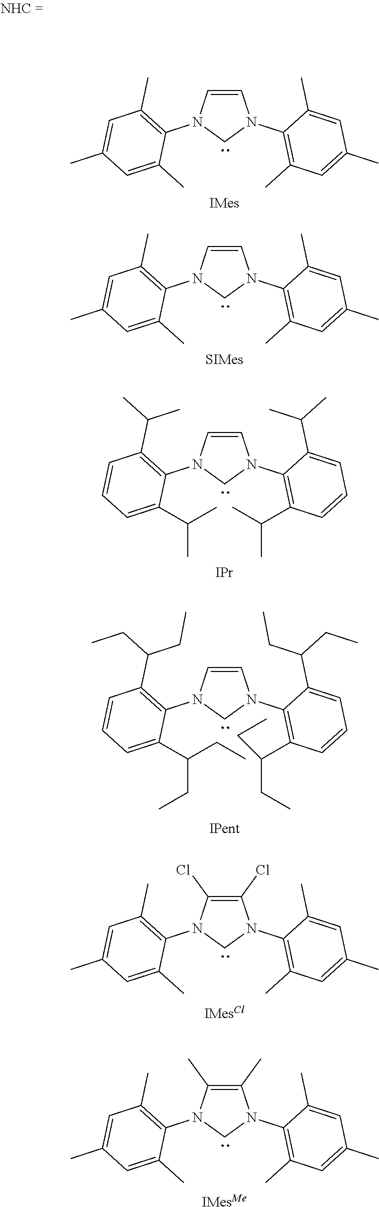

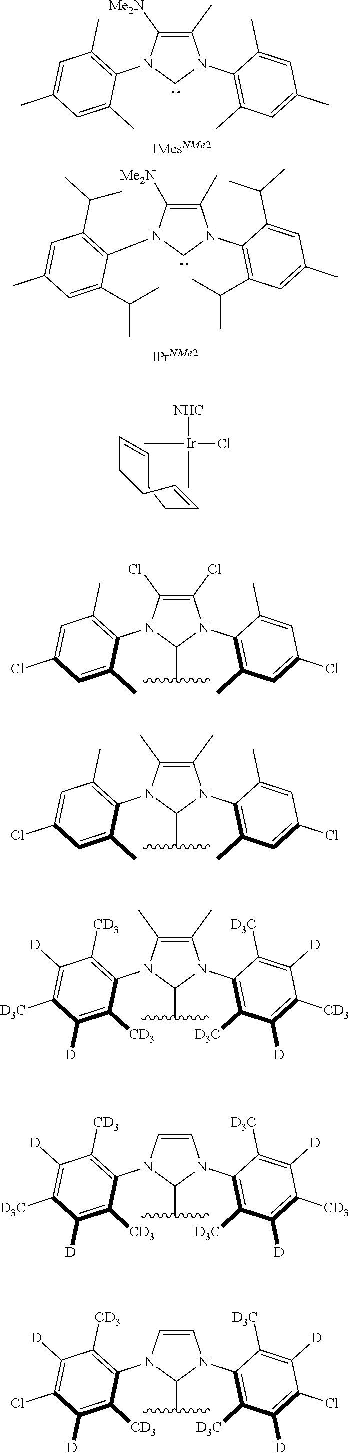

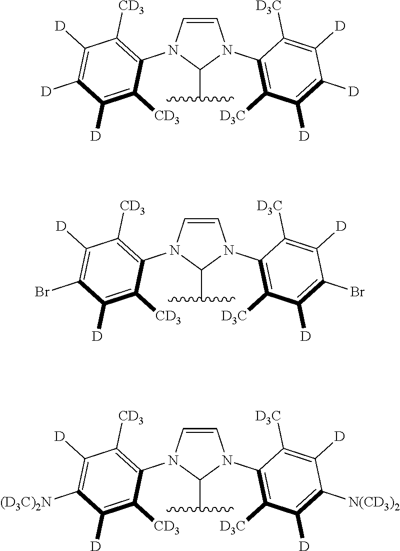

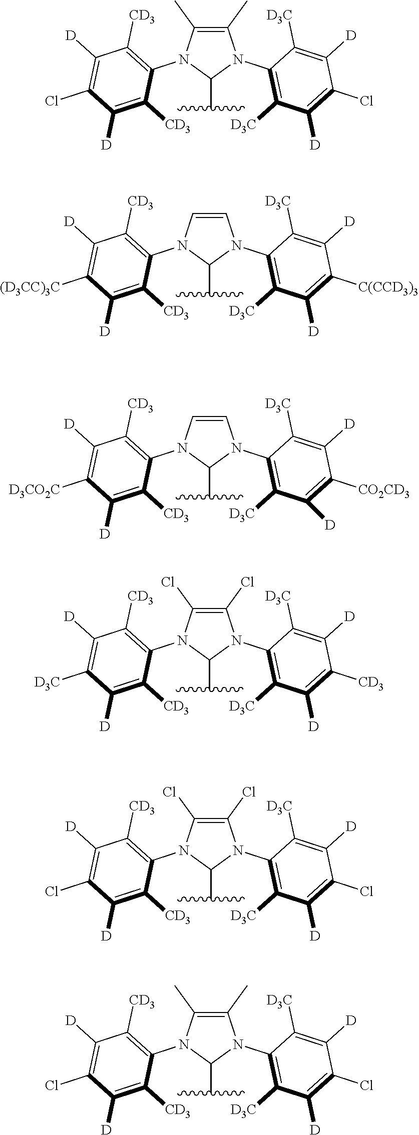

23. A method according to claim 1 wherein a co-ligand will generally be bound to the SABRE catalyst.

24. A method according to claim 23 wherein the co-ligand is selected from the group consisting of one or more of a sulfoxide, a thioester, a phosphine, an amine, CO, an isonitrile and a nitrogen heterocycle.

25. A method according to claim 23 wherein the co-ligand comprises one or more sulfoxides.

26. A method according to claim 25 wherein the sulfoxide co-ligands are selected from sulfoxides, such as, alkylsulfoxides, including, but not limited to, dimethylsulfoxide, diethylsulfoxide, dibutylsulfoxide and methylethylsulfoxide; and arylsulfoxides, including, but not limited to, diphenylsulfoxide, dibenzysulfoxide, phenylmethylsulfoxide, phenylethylsulfoxide, phenylvinyl sulfoxide and dimesityl sulfoxide (1,3,5-trimethyl-2-(2,4,6-trimethylphenyl)sulfinylbenzene.

27. A method according to claim 15 wherein the SABRE hyperpolarisation catalyst comprises iridium with at least one N-heterocyclic carbene (NHC) ligand or phosphine.

28. A method according to claim 25 wherein the sulfoxide ligand may be changed with suitable representative examples being diphenyl sulfoxide, dibutyl sulfoxide, dibenzyl sulfoxide, phenylmethyl sulfoxide, phenylethyl sulfoxide, phenylvinyl sulfoxide, dimesityl sulfoxide.

29.-40. (canceled)
